(19) United States
(12) Patent Application Publication
(10) Pub. No.: US 2026/0190825 A1
(43) Pub. Date: Jul. 2, 2026

(54) DISPLAY DEVICE

(71) Applicant: LG Display Co., Ltd., Seoul (KR)

(72) Inventors: Sookhee JEONG, Paju-si (KR); Yongmin KIM, Paju-si (KR); JungSun BAEK, Paju-si (KR); Seongjoo LEE, Paju-si (KR)

(73) Assignee: LG Display Co., Ltd., Seoul (KR)

(21) Appl. No.: 19/294,897

(22) Filed: Aug. 8, 2025

(30) Foreign Application Priority Data
Dec. 27, 2024 (KR) 10-2024-0198990

(51) Int. Cl. H10K 59/80; H10K 59/122; H10K 59/124

(52) U.S. Cl. CPC H10K 59/8792; H10K 59/122; H10K 59/124

(57) ABSTRACT

A display device includes a substrate, a first planarization layer on the substrate, a second planarization layer on the first planarization layer, and a hole through the second planarization layer. A light emitting element is disposed in the hole and the second planarization layer has a first inclined surface and a second inclined surface defining the hole. A black bank is located between the first inclined surface and the second inclined surface. The first and second inclined surfaces and the black bank reflect light and cause reflected light to exit the display device to improve display characteristics.

### CROSS REFERENCE TO RELATED APPLICATION

This application claims priority from Korean Patent Application No. 10-2024-0198990, filed on Dec. 27, 2024 in the Korean Intellectual Property Office, which is hereby incorporated by reference for all purposes as if fully set forth herein.

### BACKGROUND

### Technical Field

The present disclosure relates to electronic devices, and more specifically but not exclusively, to display devices.

### Description of the Related Art

In today's information society, display devices for presenting images or visual information to users are increasingly important. The need for such display devices has caused developments in display technology, and various types of display devices, such as a liquid crystal display (LCD) device, an organic light emitting diode (OLED) display device, and the like, have been developed and used.

Display devices may suffer from a situation where some of the light emitted from a light emitting element layer cannot exit a display panel due to total reflection between the light emitting element layer and an electrode or an organic layer, and thereby, light extraction efficiency is reduced. Further, in display devices, reflection sensitivity may be reduced and viewing angle characteristics may be reduced due to external light entering the display devices.

### BRIEF SUMMARY

To address these issues, one or more aspects of the present disclosure provide a display device capable of improving reflection sensitivity and implementing viewing angle characteristics.

One or more aspects of the present disclosure provide a display device having a structure where light emitted from a light emitting element can be absorbed by a bank, or light trapped inside of a display panel due to total reflection can be caused to exit the display panel.

According to one or more example embodiments of the present disclosure, a display device can be provided that includes a substrate, a first planarization layer disposed on the substrate, a second planarization layer disposed on the first planarization layer, and having a first hole allowing a first light emitting element to be disposed and having an inner surface including a first inclined surface and a second inclined surface and a second hole different from the first hole, a first pixel electrode disposed on the first planarization layer in the first hole and extending along the first inclined surface and the second inclined surface to an upper surface of the second planarization layer, a first black bank located in the second hole, a second black bank located on the second planarization layer, a third black bank located between the first inclined surface and the second inclined surface, a non-black bank disposed on the first black bank, the second black bank, the third black bank, and the first pixel electrode, a first intermediate layer disposed on a portion of the first pixel electrode and the non-black bank, and a common electrode disposed on the first intermediate layer.

According to one or more example embodiments of the present disclosure, a display device can be provided that includes a substrate, a first planarization layer disposed on the substrate, a second planarization layer disposed on the first planarization layer, and having a first hole allowing a first light emitting element to be disposed and having an inner surface including a first inclined surface and a second inclined surface and a second hole different from the first hole, a first pixel electrode disposed on the first planarization layer in the first hole and extending along the first inclined surface and the second inclined surface to an upper surface of the second planarization layer, a bank disposed on the first pixel electrode and the second planarization layer, a first intermediate layer disposed on a portion of the first pixel electrode and the bank, and a common electrode disposed on the first intermediate layer. In one or more aspects, a first angle formed by the first inclined surface and the back surface of the second planarization layer is less than a second angle formed by the second inclined surface and the back surface of the second planarization layer.

According to one or more aspects of the present disclosure, a display device is provided that is capable of improving reflection sensitivity and implementing viewing angle characteristics by including a structure where a planarization layer has an inclined surface, and a black bank is disposed on a pixel electrode on the planarization layer except for the inclined surface,

According to one or more aspects of the present disclosure, a display device is provided that includes a structure where an electrode of a light emitting element has a plurality of inclined surfaces, and is capable of causing light emitted from the light emitting element to exit a display panel by changing paths of light absorbed by a bank or trapped inside of the display panel due to total reflection.

According to one or more aspects of the present disclosure, a display device is provided that is capable of enabling process optimization by an improved light extraction structure without a separate additional process.

Aspects, examples, and embodiments of the present disclosure are not limited to the foregoing description, and additional aspects, examples, and embodiments of the present disclosure will become apparent to those skilled in the art from the following description. Effects, benefits, or advantages from aspects, examples, and embodiments described herein are not limited thereto, and additional effects or advantages will become apparent to those skilled in the art from the following description.

### BRIEF DESCRIPTION OF THE SEVERAL VIEWS OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an embodiment of a system configuration of a display device according to aspects of the present disclosure;

FIG. 2 illustrates a display panel of the display device of FIG. 1;

FIG. 3 is a cross-sectional view of the display panel of FIG. 2 along line A-A in FIG. 2;

FIG. 4 is a plan view of the display panel of FIG. 2;

FIGS. 5 to 8 are cross-sectional views of embodiments of the display panel of FIG. 4 taken along line A-B of FIG. 4 according to aspects of the present disclosure;

FIG. 9 is a cross-sectional view of an embodiment of the display panel of FIG. 4 taken along line A-C of FIG. 4 according to aspects of the present disclosure; and

FIG. 10 is a plan view of an embodiment of a light emitting area of the display panel of FIG. 2 according to aspects of the present disclosure.

FIG. 11 is a plan view of an embodiment of a plurality of light emitting areas of the display panel of FIG. 2 according to aspects of the present disclosure.

### DETAILED DESCRIPTION

Reference will now be made in detail to example embodiments of the present disclosure, examples or aspects of which are illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through the following example embodiments described with reference to the accompanying drawings.

The present disclosure may, however, be embodied in different forms and should not be construed as limited to the example embodiments set forth herein. Rather, these example embodiments are provided so that this disclosure is sufficiently thorough and complete to assist those skilled in the art to fully understand the scope of the present disclosure. Further, the scope of the claims and their equivalents is not limited by the present disclosure. In the following description, where the detailed description of the relevant known function or configuration may unnecessarily obscure aspects of the present disclosure, a detailed description of such known function or configuration is omitted. The shapes, sizes, ratios, angles, numbers, and the like, which are illustrated in the drawings to describe various example embodiments of the present disclosure, are merely given by way of example in some embodiments. In some embodiments, the shapes, sizes, ratios, angles, numbers, and the like illustrated in the drawings are to scale and intended to represent features of the disclosure.

The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Although the terms “first,” “second,” A, B, (a), (b), and the like are used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “contact,” “overlap with,” or the like each other via a fourth element. Here, the second element may be included in at least one of two or more elements that “are connected or coupled to,” “contact,” “overlap with,” or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, etc., are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Unless otherwise noted, such tolerance or error range is plus or minus 5% of the stated value. Thus, for example, a dimension stated as 10 cm is interpreted as 9.5 cm to 10.5 cm unless the context dictates otherwise. Further, the term “may” fully encompasses all the meanings of the term “can”.

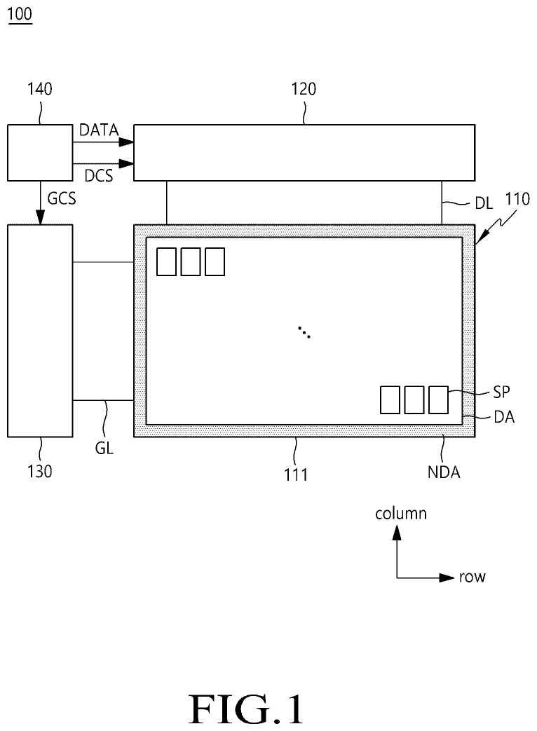

FIG. 1 illustrates an example system configuration of a display device 100 according to aspects of the present disclosure.

Referring to FIG. 1, in one or more example embodiments, the display device 100 includes a display panel 110 and at least one display driving circuit as elements for displaying images. The at least one display driving circuit may be one or more circuits for driving the display panel 110. The at least one display driving circuit includes a data driving circuit 120, a gate driving circuit 130, a controller 140, and other circuit components, but aspects of the present disclosure are not limited thereto.

The display panel 110 includes a substrate 111 and a plurality of subpixels SP disposed on the substrate 111.

The substrate 111 includes a display area DA and a non-display area NDA.

The display area DA is an area allowing an image to be displayed or configured to display an image, and may also be referred to as an active area. A plurality of subpixels SP for displaying images are disposed in the display area DA. The non-display area NDA is an area where an image is not displayed, and be an area outside of the display area DA. The non-display area NDA may also be a non-active area, a bezel area, or a bezel. The non-display area NDA includes a pad area.

The non-display area NDA includes a first non-display area, a second non-display area, a third non-display area, and a fourth non-display area. The first non-display area is located outside of the display area DA in a row direction. The second non-display area is located outside of the display area DA in the row direction and be located on the opposite side of the first non-display area. The third non-display area is located outside of the display area DA in a column direction. The fourth non-display area is located outside the display area DA in the column direction and be located on the opposite side of the third non-display area. In other words, the four non-display areas may surround the display area DA with one non-display area on each side of the display area DA.

Among the first to fourth non-display areas, the fourth non-display area includes a pad area where a driving circuit is connected or bonded, and the first to third non-display areas may have a very small size. However, aspects of the present disclosure are not limited thereto.

In one or more aspects, a boundary area is defined between the display area DA and the non-display area NDA. In this example, the boundary area is bent at a certain angle to the display area DA, and thereby, the non-display area NDA is located under the display area DA.

In this implementation, when a user views the display device 100 in front thereof, all or most of the non-display area NDA is invisible to the user, but aspects of the present disclosure are not limited thereto.

In one or more aspects, the display device 100 is a self-emissive display device in which light is emitted from the display panel 110 itself, but aspects of the present disclosure are not limited thereto. In an example where the display device 100 is the self-emissive display device, each of a plurality of subpixels SP included in the display panel 110 includes a light emitting element.

The display device 100 according to aspects of the present disclosure is an organic light emitting display device in which light emitting elements are implemented using organic light emitting diodes (OLED). In another example, the display device 100 according to aspects of the present disclosure is an inorganic light emitting display device in which light emitting elements are implemented using inorganic material-based light emitting diodes. In another example, the display device 100 according to aspects of the present disclosure is a quantum dot display device in which light emitting elements are implemented using quantum dots, which are self-emission semiconductor crystals. In another example, the display device 100 according to aspects of the present disclosure is a micro LED display device, a mini LED display device, or the like.

The structure of each of a plurality of subpixels SP included in the display panel 110 may depend on the type of display device 100. In an example where the display device 100 is a self-emissive display device including self-emissive subpixels SP, each subpixel SP includes a self-emissive light emitting element, one or more transistors, and one or more capacitors, but aspects of the present disclosure are not limited thereto.

Several types of signal lines for driving a plurality of subpixels SP may be disposed on the substrate 111 of the display panel 110. The several types of signal lines includes, for example, a plurality of data lines DL for delivering data signals (which may be referred to as data voltages or image signals) to the plurality of subpixels SP, a plurality of gate lines GL for delivering gate signals (which may be referred to as scan signals) to the plurality of subpixels SP, and the like.

In one or more aspects, the plurality of data lines DL and the plurality of gate lines GL may intersect each other. Each of the plurality of gate lines GL may extend in a first direction (e.g., a row or column direction). Each of the plurality of data lines DL may extend in a second direction (e.g., the column or row direction) different from the first direction.

The first direction may be the row direction, and the second direction may be the column direction. In another example, the first direction may be the column direction, and the second direction may be the row direction. Herein, the row direction and the column direction may not be absolute directions, but relative directions. The column direction may be the row direction and the row direction may be the column direction depending on a direction at which the display device 100 or the display panel 110 is viewed. Hereinafter, for convenience of explanation, discussions may be provided based on examples where each of a plurality of data lines DL is disposed in the column direction, and each of a plurality of gate lines GL is disposed in the row direction, but aspects of the present disclosure are limited thereto. Herein, an angle between the first direction and the second direction may be vertical (or 90 degrees) or an angle different from the vertical. For reference, FIG. 1 illustrates the “row direction” as a left-right direction and the “column direction” as an up-down direction based on the orientation of the display device 100 in FIG. 1.

The data driving circuit 120 is a circuit for driving a plurality of data lines DL and can output data signals to the plurality of data lines DL.

The data driving circuit 120 can receive image data DATA in digital form from the controller 140, convert the received image data DATA into data signals (or data voltages) in analog form, and output the resulting data signals to the plurality of data lines DL.

The data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more aspects, the data driving circuit 120 is located in, and/or electrically connected to, but not limited to, only one side or edge (e.g., an upper portion or a lower portion) of the display panel 110. In one or more aspects, the data driving circuit 120 is disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 is connected to an area located outside of the display area DA of the display panel 110, or be disposed in the display area DA of the display panel 110.

The gate driving circuit 130 is a circuit for driving a plurality of gate lines GL and can supply gate signals to the plurality of gate lines GL.

The gate driving circuit 130 can receive several types of gate driving control signals GCS, and a first gate voltage corresponding to a turn-on voltage (or a turn-on level voltage) and a second gate voltage corresponding to a turn-off voltage (or a turn-off level voltage). Thereby, the gate driving circuit 130 can generate a gate signal including a period with the first gate voltage and a period with the second gate voltage during a certain period of time (e.g., a period of one frame time or a sub-period of the period of one frame time), and supply the generated gate signals to the plurality of gate lines GL. The turn-on level voltage may be a high level voltage and the turn-off level voltage may be a low level voltage. In another example, the turn-on level voltage may be a low level voltage and the turn-off level voltage may be a high level voltage.

In one or more aspects, the gate driving circuit 130 included in the display device 100 is embedded into the display panel 110 by a gate-in-panel (GIP) technique, but aspects of the present disclosure are not limited thereto. In an example where the gate driving circuit 130 is implemented by the gate-in-panel (GIP) technique, the gate driving circuit 130 is disposed on the substrate 111 of the display panel 110 during the process of manufacturing the display panel 110 or display device 100. Herein, the gate driving circuit 130 embedded in the display panel 110 by the gate-in-panel (GIP) technique may also be referred to as a “gate-in-panel circuit.”

The gate driving circuit 130 is disposed in the non-display area NDA of the display panel 110. In another example, the gate driving circuit 130 is disposed in the display area DA of the display panel 110. In one or more aspects, the gate driving circuit 130 is disposed in, and/or electrically connected to, but not limited to, a first area (e.g., a left portion or a right portion) in the display area DA of the display panel 110. In one or more aspects, the gate driving circuit 130 is disposed in, and/or electrically connected to, but not limited to, a first area (e.g., a left portion or a right portion) in the display area DA, and a second area (e.g., the right portion or the left portion) in the display area DA. In one or more aspects, the gate driving circuit 130 is disposed in all or one or more of areas of the display area DA.

In an example where the gate driving circuit 130 is disposed in the display area DA of the display panel 110, the gate driving circuit 130 may vertically overlap with one or more subpixels SP disposed in the display area DA. The gate driving circuit 130 may vertically overlap with one or more light emitting elements and one or more transistors included in one or more subpixels SP disposed in the display area DA. The gate driving circuit 130 may vertically overlap with a plurality of light emitting elements and a plurality of transistors included in a plurality of subpixels SP disposed in the display area DA. The gate driving circuit 130 includes a plurality of transistors. Each of the plurality of transistors included in the gate driving circuit 130 includes an active layer including a first semiconductor material, and each of the plurality of transistors included in the subpixels SP includes an active layer including a second semiconductor material. The first semiconductor material and the second semiconductor material may be substantially the same. In another example, the first semiconductor material and the second semiconductor material may be different from each other. The first semiconductor material may be a silicon-based semiconductor material (e.g., a low temperature poly silicone (LTPS)), and the second semiconductor material may be an oxide semiconductor material. The active layer may be a semiconductor layer, but aspects of the present disclosure are not limited thereto.

The controller 140 is a device for controlling the data driving circuit 120 and the gate driving circuit 130, and can control driving timing for a plurality of data lines DL and driving timing for a plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 is one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and is electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces includes a low voltage differential signaling (LVDS) interface, an embedded clock point-point interface (EPI), a serial peripheral interface (SPI), and the like. However, aspects of the present disclosure are not limited thereto.

In one or more aspects, in addition to an image display function, the display device 100 can provide a touch sensing function of detecting the presence or absence of a touch by an object such as a finger, a pen, or the like, or a location of the touch.

In some aspects, the display device 100 is a mobile terminal such as a smart phone, a tablet, or the like, or a monitor, a television (TV), or the like. Such devices may be configured in various types, sizes, and shapes. The display device 100 according to aspects of the present disclosure is applied to mobile devices, video phones, smart watches, watch phones, wearable devices, foldable devices, rollable devices, bendable devices, flexible devices, stretchable devices, curved devices, sliding devices, variable devices, electronic notebooks, e-books, portable multimedia players (PMP), personal digital assistants (PDA), MP3 players, mobile medical devices, desktop PCs, laptop PCs, netbook computers, workstations, navigation devices, car navigation devices, vehicle display devices, vehicle apparatuses, theater apparatuses, theater display devices, televisions, wallpaper devices, signage devices, game devices, notebook computers, monitors, cameras, camcorders, and home appliances, and the like.

In one or more aspects, the display device 100 may further include an electronic device such as a camera (or image sensor), a sensor capable of detecting an object, ambient light, etc., and the like. The sensor is a sensor capable of detecting an object or a human body by receiving light such as infrared light, ultrasonic light, ultraviolet light or the like. However, aspects of the present disclosure are not limited thereto.

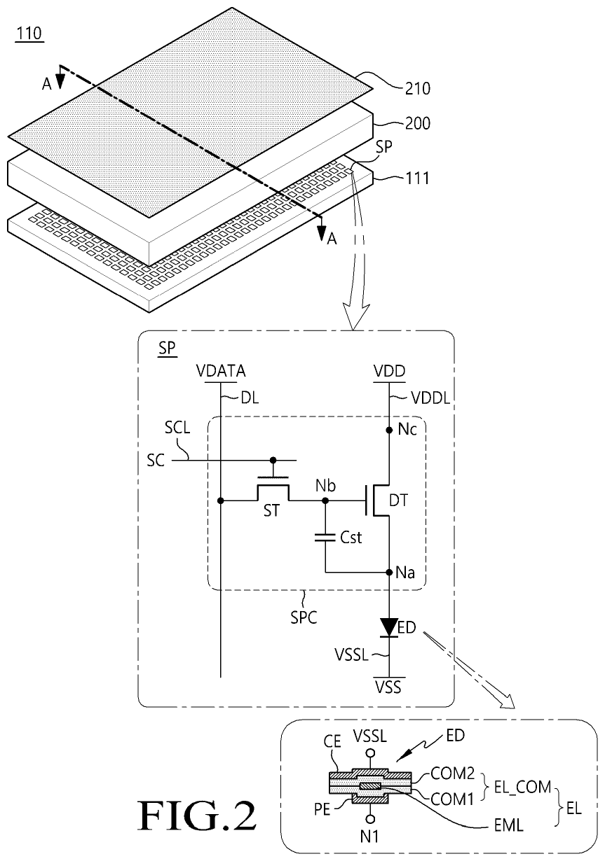

FIG. 2 illustrates an example configuration of the display panel 110 according to aspects of the present disclosure.

Referring to FIG. 2, in one or more example embodiments, the display panel 110 includes a substrate 111 on which a plurality of subpixels SP are disposed, an encapsulation layer 200 over the substrate 111, and a color filter layer 210 on the encapsulation layer 200. The encapsulation layer 200 may be referred to as an encapsulation substrate or an encapsulation part.

In the example where the display device 100 is a self-emissive display device, each of the plurality of subpixels SP disposed on the substrate 111 includes a light emitting element ED and a subpixel circuit SPC for driving the light emitting element ED.

The subpixel circuit SPC includes a plurality of transistors and at least one capacitor for driving the light emitting element ED, but aspects of the present disclosure are not limited thereto. In one or more aspects, the subpixel circuit SPC can drive the light emitting element ED by supplying a driving current to the light emitting element ED at a predefined timing. The light emitting element ED can emit light by being driven by the driving current.

The plurality of transistors includes a driving transistor DT for driving the light emitting element ED and a scan transistor ST configured to be turned on or off by a scan signal SC.

The driving transistor DT can supply a driving current to the light emitting element ED. The scan transistor ST is configured to control an electrical state of a corresponding node in the subpixel circuit SPC or to control the state or operation of the driving transistor DT. The at least one capacitor includes a storage capacitor Cst configured to maintain a voltage at a constant level during a display frame or a certain period of the display frame.

To drive one or more subpixels SP, at least one data signal VDATA, which is an image signal, and at least one scan signal SC, which is a gate signal, is applied to the one or more subpixels SP. Further, to drive one or more subpixels SP, common driving signals including a driving voltage VDD and a base voltage VSS are supplied to the one or more subpixels SP.

The light emitting element ED includes a pixel electrode PE, an intermediate layer EL, and a common electrode CE. The intermediate layer EL is disposed between the pixel electrode PE and the common electrode CE.

The pixel electrode PE is an electrode disposed for each subpixel SP such that there is one pixel electrode PE for each subpixel SP, and the common electrode CE is an electrode commonly disposed in all or some of a plurality of subpixels SP. The pixel electrode PE is an anode, and the common electrode CE is a cathode. In another example, the pixel electrode PE is a cathode, and the common electrode CE is an anode. Hereinafter, for convenience of explanation, the description describes embodiments where the pixel electrode PE is an anode, and the common electrode CE is a cathode.

In an example where the light emitting element ED is an organic light emitting diode, the intermediate layer EL includes an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML is disposed for each subpixel SP, or is commonly disposed across all or some of a plurality of subpixels SP. The common intermediate layer EL_COM is commonly disposed across all or some of a plurality of subpixels SP, but aspects of the present disclosure are not limited thereto. The emission layer EML can be formed as a single layer or multiple layers. Where the emission layer EML is multiple layers, the emission layers EML can have a tandem or stacked structure to increase light output with overall lower power consumption for the display.

The emission layer EML is disposed for each light emitting area, or be commonly disposed across all or some of a plurality of light emitting areas. The common intermediate layer EL_COM is commonly disposed across all or some of a plurality of light emitting areas and a non-light emitting area, but aspects of the present disclosure are not limited thereto.

The first common intermediate layer COM1 includes a hole injection layer (HIL), an electron blocking layer (EBL), a hole transfer layer (HTL), and the like, but aspects of the present disclosure are not limited thereto. The second common intermediate layer COM2 includes an electron transfer layer (ETL), a hole blocking layer (HBL), an electron injection layer (EIL), and the like, but aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

The common electrode CE is electrically connected to a base voltage line VSSL. A base voltage VSS, which is a type of common voltage, is applied to the common electrode CE through the base voltage line VSSL. The pixel electrode PE is electrically connected directly or indirectly (via another transistor) to a first node N1 of the corresponding driving transistor DT of each subpixel SP. Herein, the base voltage VSS may also be referred to as a first common voltage, a low power supply voltage, or a low voltage, and the base voltage line VSSL may also be referred to as a first common voltage line, a low power supply voltage line, or a low voltage line.

Each light emitting element ED is configured by stacking of a pixel electrode PE, an emission layer EML in an intermediate layer EL, and a common electrode CE. A respective light emitting area is formed by each light emitting element ED. For example, a respective light emitting area of each light emitting element ED includes an area where a pixel electrode PE, an emission layer EML in an intermediate layer EL, and a common electrode CE overlap with each other.

In one or more aspects, each, or one or more, of the light emitting elements ED included in the display panel 110 is an organic light emitting diode (OLED), an inorganic light emitting diode (LED), a quantum dot light emitting element, a micro LED, or a mini LED, but aspects of the present disclosure are not limited thereto. In the example where each light emitting element ED is an organic light emitting diode (OLED), the corresponding intermediate layer EL of each light emitting element ED is a layer including an organic material.

Referring to FIG. 2, the driving transistor DT is a transistor configured to supply a driving current to the light emitting element ED. The driving transistor DT is connected between a driving voltage line VDDL and the light emitting element ED.

The driving transistor DT includes a first node Na, a second node Nb, and a third node Nc. The first node Na is electrically connected to the light emitting element ED. A data signal VDATA is applied to the second node Nb. A driving voltage VDD, which is a type of common voltage, delivered through the driving voltage line VDDL is applied to the third node Nc. Herein, the driving voltage VDD may also be referred to as a second common voltage, a high power supply voltage, or a high voltage, and the driving voltage line VDDL may also be referred to as a second common voltage line, a high power supply voltage line, or a high voltage line.

In the driving transistor DT, the second node Nb is a gate node, the first node Na is a source node or a drain node, and the third node Nc is the drain node or the source node. Hereinafter, merely for convenience of explanation, the description will describe examples where the first, second, and third nodes (Na, Nb, and Nc) of the driving transistor DT are source, gate, and drain nodes, respectively. However, aspects of the present disclosure are not limited thereto.

The scan transistor ST included in the subpixel circuit SPC illustrated in FIG. 2 is a switching transistor for transferring a data signal VDATA, which is an image signal, to the second node Nb, which is the gate node of the driving transistor DT.

The scan transistor ST can be turned on or turned off by a scan signal SC, which is a type of gate signal, delivered through a scan line SCL, which is a type of gate line GL, and control an electrical connection between the second node Nb of the driving transistor DT and a data line DL. One of the drain electrode or source electrode of the scan transistor ST is electrically connected to the data line DL. The other of the source electrode or drain electrode of the scan transistor ST is electrically connected to the second node Nb of the driving transistor DT. The gate electrode of the scan transistor ST is electrically connected to the scan line SCL.

The storage capacitor Cst may be electrically connected between the first node Na and the second node Nb of the driving transistor DT. The storage capacitor Cst includes a first capacitor electrode electrically connected to the first node Na of the driving transistor DT or corresponding to the first node Na of the driving transistor DT, and a second capacitor electrode electrically connected to the second node Nb of the driving transistor DT or corresponding to the second node Nb of the driving transistor DT.

The storage capacitor Cst is an external capacitor intentionally designed to be located outside of the driving transistor DT, and therefore, be different from an internal capacitor such as a parasitic capacitor (e.g., a Cgs, a Cgd) that is formed between the first node Na and the second node Nb of the driving transistor DT. However, aspects of the present disclosure are not limited thereto.

Each of the driving transistor DT and the scan transistor ST is an n-type transistor or a p-type transistor, but aspects of the present disclosure are not limited thereto. For example, one of the driving transistor DT and the scan transistor ST is one of an n-type transistor and a p-type transistor.

The display panel 110 may have a top emission structure or a bottom emission structure. In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase. In an example where the display panel 110 has the bottom emission structure, the subpixel circuit SPC may not overlap with the light emitting element ED in the vertical direction.

As shown in FIG. 2, the subpixel circuit SPC includes two transistors (2T: DT and ST) and one capacitor (1C: Cst) (which may be referred to as a “2T1C structure”), and in some implementations, may further include one or more transistors, and/or further include one or more capacitors. However, aspects of the present disclosure are not limited thereto.

The subpixel circuit SPC may have a 3T1C structure including 3 transistors and 1 capacitor. In another example, the subpixel circuit SPC may have an 8T1C structure including 8 transistors and 1 capacitor. In another example, the subpixel circuit SPC may have a 6T2C structure including 6 transistors and 2 capacitors. In another example, the subpixel circuit SPC may have an 7T1C structure including 7 transistors and 1 capacitor. However, aspects of the present disclosure are not limited thereto.

The types and number of gate signals supplied to a subpixel SP, and/or the types and number of gate lines connected to the subpixel SP may vary depending on a structure of a corresponding subpixel circuit SPC. Further, the types and number of common driving signals supplied to a subpixel SP may vary depending on a structure of a corresponding subpixel circuit SPC.

Referring to FIG. 2, the encapsulation layer 200 is disposed in or on the display panel 110 since circuit elements (e.g., light emitting elements ED such as organic light emitting diodes (OLED) including an organic material) in each subpixel SP are vulnerable to external moisture or oxygen. The encapsulation layer 200 can prevent external moisture or oxygen from penetrating into the circuit elements (e.g., the light emitting elements ED). The encapsulation layer 200 is disposed in various shapes or configurations to prevent light emitting elements ED from contacting moisture or oxygen. The encapsulation layer 200 includes two or more layers in which one or more organic layers and one or more inorganic layers are alternately stacked, but aspects of the present disclosure are not limited thereto.

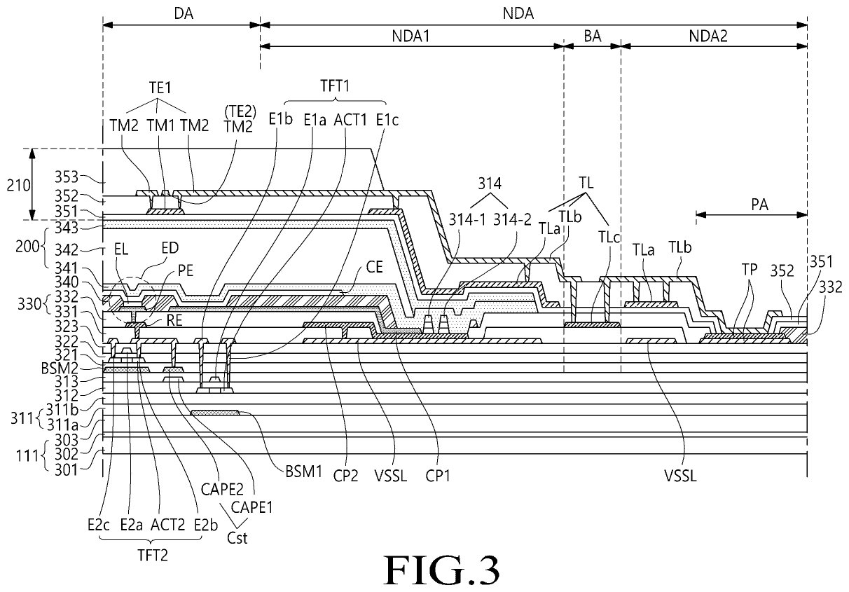

FIG. 3 is an example cross-sectional view of the display panel 110 according to aspects of the present disclosure along line A-A in FIG. 2.

Referring to FIG. 3, in one or more example embodiments, the display panel 110 includes a substrate 111, a transistor part (which may also be referred to as a transistor or a transistor stack), a light emitting element part (which may also be referred to as a light emitting element or a light emitting stack), and an encapsulation part (which may also be referred to as an encapsulation layer or layers), but aspects of the present disclosure are not limited thereto.

The substrate 111 may be in the form of a single layer or a multilayer stack. In an example where the substrate 111 includes a multilayer structure, the substrate 111 includes a first substrate 301, an intermediate substrate layer 302, and a second substrate 303. The intermediate substrate layer 302 is located between the first substrate 301 and the second substrate 303. In one or more aspects, each of the first substrate 301 and the second substrate 303 is a polyimide (PI) layer, but aspects of the present disclosure are not limited thereto. The intermediate substrate layer 302 is an inorganic insulating layer, but aspects of the present disclosure are not limited thereto. When electric charges are stored on the first substrate 301, which is a polyimide (PI) layer, the intermediate substrate layer 302 can block the charges from affecting transistors disposed on the second substrate 303 through the second substrate 303, which is a polyimide (PI) layer.

Further, the intermediate substrate layer 302 can block moisture from moving upwardly through the first substrate 301. The intermediate substrate layer 302 may be in the form of a single layer of silicon nitride (SiNx) or silicon oxide (SiOx) or a multilayer of silicon nitride (SiNx) and/or silicon oxide (SiOx), or may be in the form of double layers of silicon dioxide (SiO₂) and silicon nitride (SiNx), but aspects of the present disclosure are not limited thereto.

The transistor part includes insulating layers (311, 312, 313, 321, 322, and 323), thin film transistors (TFT1 and TFT2), a storage capacitor Cst, and several electrodes or signal lines, on the substrate 111.

The thin film transistors (TFT1 and TFT2) included in the transistor part includes a first thin film transistor TFT1 and a second thin film transistor TFT2.

The first thin film transistor TFT1 includes a first active layer ACT1, a first electrode E1a, a second electrode E1b, and a third electrode E1c.

The first electrode E1a is a gate electrode, the second electrode E1b is a source electrode or a drain electrode, and the third electrode E1c is the drain electrode or the source electrode. Hereinafter, for convenience of explanation, embodiments are described where the first, second, and third electrodes (E1a, E1b, and E1c) are a first gate electrode E1a, a first source electrode E1b, and a first drain electrode E1c, respectively. However, aspects of the present disclosure are not limited thereto.

The first active layer ACT1 includes a first semiconductor material. The first semiconductor material includes an oxide semiconductor, amorphous silicon, polysilicon, low-temperature polysilicon (LTPS), or the like, but aspects of the present disclosure are not limited thereto. The first thin film transistor TFT1 may be a p-channel transistor or an n-channel transistor, but aspects of the present disclosure are not limited thereto.

The second thin film transistor TFT2 includes a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be the drain electrode or the source electrode. Hereinafter, for convenience of explanation, further description is provided based on examples where the fourth, fifth, and sixth electrodes (E2a, E2b, and E2c) are a second gate electrode E2a, a second source electrode E2b, and a second drain electrode E2c, respectively. However, aspects of the present disclosure are not limited thereto.

The second active layer ACT2 includes a second semiconductor material. The second semiconductor material includes an oxide semiconductor, amorphous silicon, polysilicon, or low-temperature polysilicon (LTPS), or the like, but aspects of the present disclosure are not limited thereto. The second thin film transistor TFT2 is a p-channel transistor or an n-channel transistor, but aspects of the present disclosure are not limited thereto.

The types of respective semiconductor materials of the first active layer ACT1 of the first thin film transistor TFT1 and the second active layer ACT2 of the second thin film transistor TFT2 are described further below.

For example, each of the first active layer ACT1 of the first thin film transistor TFT1 and the second active layer ACT2 of the second thin film transistor TFT2 includes an oxide semiconductor material. For example, each of the first active layer ACT1 of the first thin film transistor TFT1 and the second active layer ACT2 of the second thin film transistor TFT2 includes a low-temperature polysilicon semiconductor material. The first active layer ACT1 of the first thin film transistor TFT1 includes a low-temperature polysilicon semiconductor material, and the second active layer ACT2 of the second thin film transistor TFT2 includes an oxide semiconductor material. The first active layer ACT1 of the first thin film transistor TFT1 includes an oxide semiconductor material, and the second active layer ACT2 of the second thin film transistor TFT2 includes a low-temperature polysilicon semiconductor material. However, aspects of the present disclosure are not limited thereto.

Transistors disposed in the display area DA are used as follows.

For example, all transistors included in each subpixel SP are implemented as the first thin film transistor TFT1. For example, all transistors included in each subpixel SP are implemented as the second thin film transistor TFT2. For example, one or more of transistors included in each subpixel SP may be implemented as the first thin film transistor TFT1, and the remaining one or more transistors may be implemented as the second thin film transistor TFT2. For example, each subpixel SP includes at least one first thin film transistor TFT1 and at least one second thin film transistor TFT2.

In an example where one or more of the transistors included in each subpixel SP are implemented as the first thin film transistor TFT1, and the remaining one or more transistors are implemented as the second thin film transistor TFT2, various configurations are applied as described below.

For example, in each subpixel SP, a driving transistor DT is implemented as the first thin film transistor TFT1, and the remaining one or more transistors (e.g., a scan transistor ST, an emission control transistor, and/or the like) are implemented as the second thin film transistor TFT2.

For example, in each subpixel SP, a driving transistor DT is implemented as the second thin film transistor TFT2, and the remaining one or more transistors (e.g., a scan transistor ST, an emission control transistor, and/or the like) are implemented as the first thin film transistor TFT1.

In FIG. 3, the second thin film transistor TFT2 connected to a pixel electrode PE of a light emitting element ED is a driving transistor DT or a transistor different from the driving transistor DT depending on the configuration of a corresponding subpixel circuit SPC. For example, in FIG. 3, the second thin film transistor TFT2 connected to the pixel electrode PE of the light emitting element ED is an emission control transistor connected between the driving transistor DT and the light emitting element ED. In embodiments where the second thin film transistor TFT2 is the driving transistor, the second thin film transistor TFT2 is an oxide transistor and the first thin film transistor TFT1 is an LPTS transistor, which allows for more power to provided to the subpixels to increase light output with overall lower power consumption for the display. The active layer ACT2 of the second thin film transistor TFT2 is an LTPS transistor is thinner than the active layer ACT1 of the first thin film transistor TFT1.

Transistors disposed in the non-display area NDA are used as follows.

The active layers of transistors included in the gate driving circuit of the gate-in-panel (GIP) type include an oxide semiconductor material. The active layers of transistors included in the gate driving circuit of the gate-in-panel (GIP) type include a low-temperature polysilicon semiconductor material. For example, among the active layers of transistors included in the gate driving circuit of the gate-in-panel (GIP) type, some active layers include a low-temperature polysilicon semiconductor material, and other active layers or the remaining one or more active layers include an oxide semiconductor material.

The second active layer ACT2 of the second thin film transistor TFT2 is located higher from the substrate 111 than the first active layer ACT1 of the first thin film transistor TFT1.

A first buffer layer 311 is disposed under the first active layer ACT1 of the first thin film transistor TFT1, and a second buffer layer 321 is disposed under the second active layer ACT2 of the second thin film transistor TFT2. The first active layer ACT1 of the first thin film transistor TFT1 is disposed on the first buffer layer 311, and the second active layer ACT2 of the second thin film transistor TFT2 is disposed on the second buffer layer 321. The second buffer layer 321 is disposed in a higher location than the first buffer layer 311 in the cross-sectional view.

The storage capacitor Cst is disposed in several metal layers in the display panel 110. The storage capacitor Cst includes a first capacitor electrode CAPE1 and a second capacitor electrode CAPE2.

The light emitting element part includes a plurality of light emitting elements ED disposed on at least one planarization layer 330. Each of the plurality of light emitting elements ED includes a pixel electrode PE, an intermediate layer EL, and a common electrode CE.

The encapsulation part includes an encapsulation layer 200 on the plurality of light emitting elements ED. The encapsulation layer 200 is in the form of a single layer or a multilayer structure, but aspects of the present disclosure are not limited thereto. In addition to the encapsulation layer 200, the encapsulation part further includes at least one dam 314 to prevent a material included in the encapsulation layer 200 from overflowing. For example, when a second encapsulation layer 342 included in the encapsulation layer 200 is an organic encapsulation layer including an organic material, the dam 314 prevents the organic encapsulation layer from overflowing. The dam 314 may be formed, at least in part, by the second planarization layer 332 described below. The second planarization layer 332 is a black bank or a black bank is formed instead of the second planarization layer 332 in some embodiments. In such embodiments, the black bank 332 is disposed in the pad area PA of the non-display area NDA and covers at least a portion of, or all of, a first and second source drain and additional layers that may be present beyond the first and second source drain. The dam 314 may be formed by a plurality of different layers of the display device 100. The dam 314 overlaps the first connection pattern CP1, which may be an anode in some embodiments. The dam 314 also overlaps the second connection pattern CP2, which may be one or more source drains such as a first and second source drain.

Hereinafter, a vertical structure or stack-up structure of the display panel 110 is described in more detail with reference to FIG. 3.

Referring to FIG. 3, the first buffer layer 311 is disposed on the substrate 111. The first buffer layer 311 is in the form of a single layer or a multilayer stack, but aspects of the present disclosure are not limited thereto. In an example where the first buffer layer 311 includes a multilayer structure, the first buffer layer 311 includes a lower buffer layer 311a and an upper buffer layer 311b.

The first active layer ACT1 of the first thin film transistor TFT1 is disposed on the first buffer layer 311. The first active layer ACT1 includes a channel region where a channel is formed, a source connection region on a first side of the channel region, and a drain connection region on a second opposing side of the channel region.

A first gate insulating layer 312 is disposed on the first active layer ACT1 of the first thin film transistor TFT1. The first gate electrode E1a of the first thin transistor TFT1 is disposed on the first gate insulating layer 312. A first interlayer insulating layer 313 is disposed on the first gate electrode E1a of the first thin film transistor TFT1. A metal layer in which the first gate electrode E1a of the first thin film transistor TFT1 is disposed may be referred to as a first gate metal layer.

The second buffer layer 321 is disposed on the first interlayer insulating layer 313. A second gate insulating layer 322 is disposed on the second active layer ACT2 of the second thin film transistor TFT2. The second gate electrode E2a of the second thin film transistor TFT2 is disposed on the second gate insulating layer 322. A second interlayer insulating layer 323 is disposed on the second gate electrode E2a of the second thin film transistor TFT2. The second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 is disposed on the second interlayer insulating layer 323.

The first source electrode E1b and the first drain electrode E1c of the first thin film transistor TFT1 are connected to the source connection region and the drain connection region of the first active layer ACT1, respectively, through holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second thin film transistor TFT2 are connected to the source connection region and the drain connection region of the second active layer ACT2, respectively, through holes in the second interlayer insulating layer 323 and the second gate insulating layer 322.

The first source electrode E1b and the first drain electrode E1c of the first thin film transistor TFT1, and the second source electrode E2b and the second drain electrode E2c of the second thin film transistor TFT2 include a first source-drain metal and are disposed in a first source-drain metal layer.

Referring to FIG. 3, in one or more aspects, the storage capacitor Cst includes the first capacitor electrode CAPE1 and the second capacitor electrode CAPE2. In one or more aspects, the storage capacitor Cst includes three or more capacitor electrodes, or includes two or more capacitors connected in parallel.

Each of the first capacitor electrode CAPE1 and the second capacitor electrode CAPE2 are disposed in several metal layers disposed in the display panel 110.

In one or more aspects, the first capacitor electrode CAPE1 includes the same first gate metal as the first gate electrode E1a of the first thin film transistor TFT1 on the first gate insulating layer 312 and is disposed in the first gate metal layer, but aspects of the present disclosure are not limited thereto. In one or more aspects, the second capacitor electrode CAPE2 is disposed on the first interlayer insulating layer 313.

The second source electrode E2b of the second transistor TFT2 is electrically connected to the second capacitor electrode CAPE2 through holes in the second interlayer insulating layer 323, the second gate insulating layer 322, and the second buffer layer 321.

In one or more aspects, the transistor part further includes a first shield pattern BSM1 disposed on the substrate 111. The first shield pattern BSM1 overlaps with the first active layer ACT1 of the first thin film transistor TFT1. The first shield pattern BSM1 is disposed under the first active layer ACT1 of the first thin film transistor TFT1. The first shield pattern BSM1 is disposed between the substrate 111 and the first buffer layer 311, or is disposed between the lower buffer layer 311a and the upper buffer layer 311b.

The transistor part further includes a second shield pattern BSM2 disposed on the substrate 111. The second shield pattern BSM2 overlaps with the second active layer ACT2 of the second thin film transistor TFT2. The second shield pattern BSM2 is disposed under the second active layer ACT2 of the second thin film transistor TFT2. The second shield pattern BSM2 is disposed in a metal layer between the first interlayer insulating layer 313 and the second buffer layer 321. The second shield pattern BSM2 is disposed in the same metal layer as the second capacitor CAPE2, but aspects of the present disclosure are not limited thereto. The second shield pattern BSM2 is disposed in the same first gate metal layer as the first gate electrode E1a of the first thin film transistor TFT1.

The planarization layer 330 is disposed on the first thin film transistor TFT1 and the second thin film transistor TFT2, and is disposed under the light emitting element ED. The planarization layer 330 is an organic insulating layer including an organic insulating material.

The planarization layer 330 may be in the form of a single layer. Alternatively, the planarization layer 330 includes two layers. The planarization layer 330 includes a first planarization layer 331 and a second planarization layer 332. The planarization layer 330 includes three or more layers, but aspects of the present disclosure are not limited thereto.

The first planarization layer 331 is disposed on the first source electrode E1b and the first drain electrode E1c of the first thin film transistor TFT1 and the second source electrode E2b and the second drain electrode E2c of the second thin film transistor TFT2. The first planarization layer 331 is disposed on the first thin film transistor TFT1 and the second thin film transistor TFT2. The first planarization layer 331 is disposed such that it covers both the first thin film transistor TFT1 and the second thin film transistor TFT2.

A connection electrode RE is disposed on the first planarization layer 331. The connection electrode RE electrically connects the second source electrode E2b of the second thin film transistor TFT2 and the pixel electrode PE.

The connection electrode RE is electrically connected to the second source electrode E2b of the second thin film transistor TFT2 through a hole in the first planarization layer 331. The second source electrode E2b of the second thin film transistor TFT2 is electrically connected to the second capacitor electrode CAPE2 of the storage capacitor Cst.

The connection electrode RE is disposed in a second source-drain metal layer on the first planarization layer 331, and include a second source-drain metal. The second planarization layer 332 is disposed on the connection electrode RE.

The light emitting element part is disposed on the second planarization layer 332. The light emitting element ED is formed on the second planarization layer 332. The light emitting element ED includes the pixel electrode PE, the intermediate layer EL, and the common electrode CE. A light emitting area of the light emitting element ED is formed by an area where the pixel electrode PE, the intermediate layer EL, and the common electrode CE overlap with and contact each other.

The pixel electrode PE is disposed on the second planarization layer 332. The pixel electrode PE is electrically connected to the connection electrode RE through a hole in the second planarization layer 332.

The bank 340 is disposed on the second planarization layer 332 and the pixel electrode PE. An opening of the bank 340 exposes a portion of the pixel electrode PE to form a light emitting area. The opening of the bank 340 overlaps with a portion of the pixel electrode PE.

The bank 340 includes a material including a black pigment, or an organic material including a benzocyclobutene resin, a polyimide resin, an acrylic resin, a photosensitive polymer, or the like. However, aspects of the present disclosure are not limited thereto. In an example where the bank 340 includes a material including a black pigment or a black dye, the bank 340 may be a black bank. In the example where the bank 340 includes a material including a black pigment or a black dye, the luminance of the display device can be further improved because light from the outside or light reflected from the outside can be blocked.

The intermediate layer EL of the light emitting element ED is disposed on a portion of the pixel electrode PE and the bank 340. The common electrode CE is disposed on the intermediate layer EL and the bank 340.

The encapsulation part is disposed on the light emitting element part, and is located on the common electrode CE. The encapsulation part includes an encapsulation layer 200 disposed on the common electrode CE.

The encapsulation layer 200 prevents moisture or oxygen from penetrating into the light emitting element ED. The encapsulation layer 200 can prevent moisture or oxygen from penetrating into an organic material included in the intermediate layer EL of the light emitting element ED. In one or more aspects, the encapsulation layer 200 may be in the form a single layer or a multilayer stack, but aspects of the present disclosure are not limited thereto.

The encapsulation layer 200 includes a first encapsulation layer 341, a second encapsulation layer 342, and a third encapsulation layer 343, but aspects of the present disclosure are not limited thereto. The first encapsulation layer 341 and the third encapsulation layer 343 include an inorganic material, and the second encapsulation layer 342 includes an organic material. However, aspects of the present disclosure are not limited thereto.

In one or more aspects, a touch sensor may be embedded in the display panel 110. In this implementation, the display panel 110 includes a touch sensor layer 210 disposed on the encapsulation layer 200 and including the touch sensor.

The touch sensor layer 210 includes a plurality of touch electrodes TE serving as the touch sensor, and includes at least one touch metal layer for forming the plurality of touch electrodes TE.

For example, to form the plurality of touch electrodes TE, the touch sensor layer 210 includes a first touch metal layer in which a plurality of first touch metals TM1 are disposed, and a second touch metal layer in which a plurality of second touch metals TM2 are disposed. In this implementation, the touch sensor layer 210 further includes a touch interlayer insulating layer 352 disposed between the first touch metal layer and the second touch metal layer.

For example, one of the first touch metal layer and the second touch metal layer may be a sensor metal layer, and the other may be a bridge metal layer.

The first touch metal layer is a bridge metal layer, and the second touch metal layer is a sensor metal layer. In this implementation, the plurality of second touch metals TM2 disposed in the second touch metal layer are sensor metals forming the touch sensor, and the plurality of first touch metals TM1 disposed in the first touch metal layer are bridge metals electrically connecting the plurality of second touch metals TM2, which are the sensor metals. In one or more aspects, two or more second touch metals TM2 and at least one first touch metal TM1 form one first touch electrode TE1. In this implementation, the two or more second touch electrodes TE2 are electrically connected by at least one first touch metal TM1.

In one or more aspects, the first touch metal layer is a sensor metal layer, and the second touch metal layer is a bridge metal layer. In this implementation, the plurality of first touch metals TM1 disposed in the first touch metal layer are sensor metals forming the touch sensor, and the plurality of second touch metals TM2 disposed in the second touch metal layer are bridge metals electrically connecting the plurality of first touch metals TM1, which are the sensor metals.

In one or more aspects, each of the first touch metal layer and the second touch metal layer are a sensor metal layer and a bridge metal layer. The first touch metal layer is a sensor metal layer and a bridge metal layer, and the second touch metal layer is a sensor metal layer and a bridge metal layer. In this implementation, the plurality of first touch metals TM1 disposed in the first touch metal layer includes sensor metals and bridge metals, and the plurality of second touch metals TM2 disposed in the second touch metal layer includes sensor metals and bridge metals.

The touch sensor layer 210 further includes a touch buffer layer 351 disposed on the encapsulation layer 200. The touch buffer layer 351 is disposed between the encapsulation layer 200 and the touch metal layer. The first touch metal layer is disposed on the touch buffer layer 351, and the touch interlayer insulating layer 352 is disposed on the first touch metal layer.

The touch sensor layer 210 further includes a touch protection layer 353 disposed such that the touch protection layer 353 covers the touch metal layers. The touch protection layer 353 is disposed on the second touch metal layer.

The touch buffer layer 351 is an inorganic layer including an inorganic insulating material or an organic layer including an organic insulating material. The touch interlayer insulating layer 352 is an inorganic layer including an inorganic insulating material or an organic layer including an organic insulating material. The touch protection layer 353 is an inorganic layer including an inorganic insulating material or an organic layer including an organic insulating material.

For example, at least one of the touch buffer layer 351 and the touch interlayer insulating layer 352 is disposed to extend from the display area DA to the non-display area NDA. The touch protection layer 353 is disposed to extend from the display area DA to the non-display area NDA.

A touch routing line TL electrically interconnects a touch electrode TE and a touch pad TP. The touch routing line TL is formed by at least one of the first touch metal TM1 and the second touch metal TM2.

The touch routing line TL is formed by the first touch metal TM1. The touch routing line TL is formed by the second touch metal TM2. The touch routing line TL is formed by the first touch metal TM1 and the second touch metal TM2. In an example where one touch routing line TL is formed by the first touch metal TM1 and the second touch metal TM2, the first touch metal TM1 and the second touch metal TM2 included in the touch routing line TL are electrically connected through a hole in the insulating layer 352.

For example, one touch routing line TL includes a plurality of line portions, and each of the plurality of line portions is a single line portion or a double line portion. The single line portion may be a line portion with one signal path, and the double line portion may be a line portion with two signal paths connected in parallel.

The touch routing line TL extends along an inclined surface of the encapsulation layer 200, extends over an upper portion of at least one dam (314-1 and/or 314-2), and reaches or contacts a touch pad TP.

The touch buffer layer 351 has an opening to expose at least a portion of the touch pad TP. The touch routing line TL is electrically connected to the touch pad TP through the opening of the touch buffer layer 351. The touch interlayer insulating layer 352 is disposed on a portion of the touch routing line TL and extends to an area where the touch pad TP is disposed. The touch protection layer 353 is disposed only in the display area DA, or may extend to the non-display area NDA and be disposed on the touch routing line TL. In one or more aspects, the touch protection layer 353 extends further to an upper portion of the touch pad TP.

Each of a plurality of touch electrodes TE may be a mesh-type electrode configured to have a mesh and having a plurality of openings. In this implementation, each of the plurality of touch electrodes TE includes at least one second touch metal TM2, but aspects of the present disclosure are not limited thereto.

The plurality of touch electrodes TE includes at least one first touch electrode TE1 and at least one second touch electrode TE2. In an example where the first touch metal layer is a bridge metal layer and the second touch metal layer is a sensor metal layer, two or more second touch metals TM2 included in a first touch electrode TE1, which is the touch sensor, are electrically connected through at least one first touch metal TM1, which is the bridge metal. For example, two second touch metals TM2 spaced apart from each other are electrically connected by a first touch metal TM1 to form one first touch electrode TE1.

The plurality of first touch metals TM1 and the plurality of second touch metals TM2 are disposed not to overlap with the light emitting element ED. The plurality of first touch metals TM1 and the plurality of second touch metals TM2 overlap with the bank 340. According to these configurations, the display panel 110 can provide an advantage of improving the emission efficiency of the light emitting element ED.

The touch routing line TL connects the touch pad TP disposed in a pad area PA of a second non-display area NDA2 and the first touch electrode TE1 disposed in the display area DA. In this implementation, the touch routing line TL is disposed across the second non-display area NDA2, a bending area BA, and a first non-display area NDA1.

The touch routing line TL includes a first line portion TLa, a second line portion TLb, and a third line portion TLc. The touch routing line TL includes the first line portion TLa and the second line portion TLb disposed in the first non-display area NDA1 and the second non-display area NDA2, and the third line portion TLc disposed in the bending area BA. The third line portion TLc connects two first line portions TLa or the first line portion TLa and the second line portion TLb.

The first line portion TLa of the touch routing line TL is a single line portion and further includes a third touch metal layer in which a third touch metal TM3 is disposed.

The first line portion TLa of the touch routing line TL is disposed to extend along an inclined surface of the encapsulation layer 200, and further extend over at least one dam (314-1 and/or 314-2).

The first line portion TLa of the touch routing line TL is connected to the third line portion TLc of the touch routing line TL through at least one of the first touch metal layer and the second touch metal layer.

The second line portion TLb of the touch routing line TL includes at least one of the first touch metal layer in which the first touch metal TM1 is disposed and the second touch metal layer in which the second touch metal TM2 is disposed.

The second line portion TLb of the touch routing line TL may be formed by the second touch metal layer. For another example, the second line portion TLb of the touch routing line TL may be formed by an electrical connection of the first touch metal layer and the second touch metal layer.

The second line portion TLb of the touch routing line TL is electrically connected to the touch pad TP through a contact hole (opening) through the second planarization layer 332, the touch buffer layer 351, and the touch interlayer insulation layer 352.

The third line portion TLc of the touch routing line TL is connected to the second line portion TLb of the touch routing line TL.

The third line portion TLc of the touch routing line TL includes a metal layer different from the first to third touch metal layers in which the first and second touch metals (TM1, TM3, and TM3) are disposed. The metal layer included in the third line portion TLc of the touch routing line TL is the same as a metal layer in which one or more electrodes or lines for display driving are disposed. The metal layer included in the third line portion TLc of the touch routing line TL includes a metal layer in which the pixel electrode PE is disposed, but aspects of the present disclosure are not limited thereto.

The touch pad TP is electrically connected to the second line portion TLb of the touch routing line TL and includes a metal layer different from the first to third touch metal layers. The metal layer included in the touch pad TP is the same as a metal layer in which one or more electrodes or lines for display driving are disposed. The metal layer included in the touch pad TP includes a metal layer in which the pixel electrode PE is disposed, but aspects of the present disclosure are not limited thereto.

In one or more aspects, the display panel 110 further includes a common voltage line VSSL to which a common voltage VSS is applied, and a connection pattern CP for connecting the common electrode CE and the common voltage line VSSL.

The connection pattern CP includes a first connection pattern CP1 and a second connection pattern CP2.

The first connection pattern CP1 connects the common electrode CE and the second connection pattern CP2, and the second connection pattern CP2 connects the first connection pattern CP1 and the first common voltage line VSSL, but aspects of the present disclosure are not limited thereto.

The first connection pattern CP1 includes the same material as the pixel electrode PE. The second connection pattern CP2 includes the same material as the connection electrode RE.

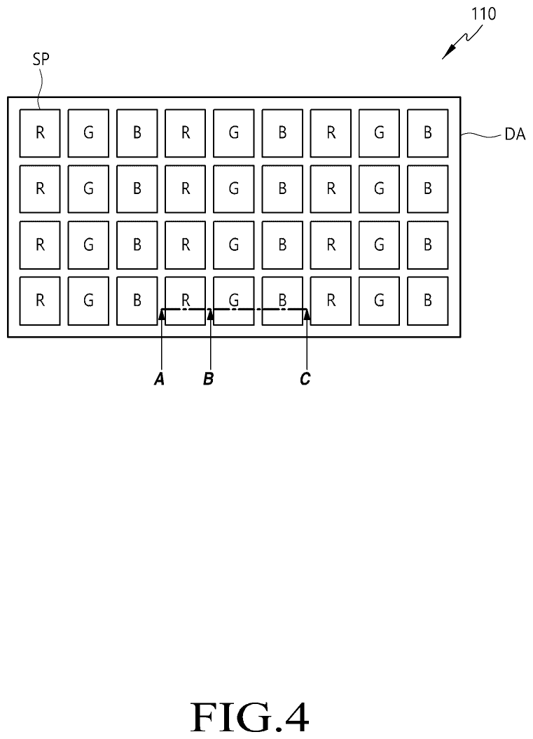

FIG. 4 is an example plan view of the display panel 110 according to aspects of the present disclosure.

Referring to FIG. 4, in one or more example embodiments, the display panel 110 includes a plurality of subpixels SP. The subpixels SP are disposed in the display area DA for displaying images. Each of the subpixels SP includes a light emitting element configured to emit red light R, green light G, or blue light B.

In one or more aspects, the display device 100 may be a TV, a monitor, or the like. In one or more aspects, the display device 100 may be a smart phone, a tablet, a wearable electronic device, or the like. In one or more aspects, the display device 100 may be a vehicle display, a virtual reality (VR) electronic device, an augmented reality (AR) electronic device, or the like.

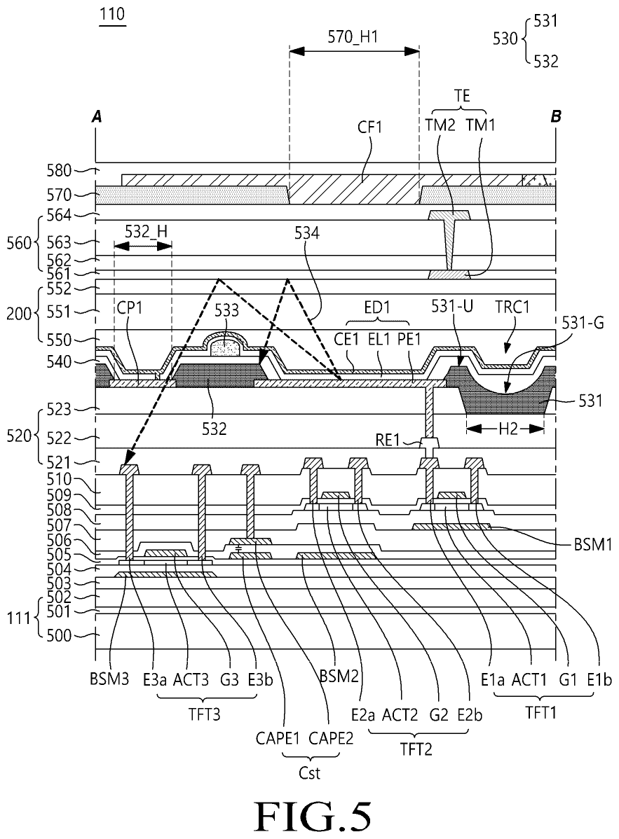

FIGS. 5 to 8 are example cross-sectional views taken along line A-B of FIG. 4 according to embodiments of the present disclosure. Hereinafter, description for features equal, substantially equal, or similar to the features described with reference to FIG. 3 are omitted for simplicity.

Referring to FIG. 5, in one or more example embodiments, the display panel 110 includes a substrate 111, a transistor part, a light emitting element part, and an encapsulation part, but aspects of the present disclosure are not limited thereto.

The substrate 111 includes a single layer or a multilayer stack or structure. In an example where the substrate 111 includes a multilayer structure, the substrate 111 includes a first substrate 500, an intermediate substrate layer 501, and a second substrate 502. The intermediate substrate layer 501 is located between the first substrate 500 and the second substrate 502 with each of the first substrate, intermediate substrate layer 501, and second substrate 502 in direct contact to form the multi-layer stack of the substrate 111.

For example, each of the first substrate 500 and the second substrate 502 are a polyimide (PI) layer, but aspects of the present disclosure are not limited thereto. The intermediate substrate layer 501 is an inorganic insulating layer, but aspects of the present disclosure are not limited thereto. When electric charges are stored on the first substrate 500, which is a polyimide (PI) layer, the intermediate substrate layer 501 can block the charges from affecting transistors disposed on the second substrate 502 through the second substrate 502, which is a polyimide (PI) layer. Thus, the intermediate substrate layer 501 may be shielding layer or an insulating layer.

Further, the intermediate substrate layer 501 can block moisture from moving upwardly through the first substrate 500. The intermediate substrate layer 501 may be in the form of a single layer of silicon nitride (SiNx) or silicon oxide (SiOx) or a multilayer stack or structure of silicon nitride (SiNx) and/or silicon oxide (SiOx), or be in the form of double layers of silicon dioxide (SiO₂) and silicon nitride (SiNx), but aspects of the present disclosure are not limited thereto.

The transistor part includes, but is not limited to, insulating layers (503, 504, 505, 506, 507, 508, 509, and 510) on the substrate 111, thin film transistors (TFT1, TFT2, and TFT3), a storage capacitor Cst, and various electrodes or signal lines.

The thin film transistors (TFT1, TFT2, and TFT3) included in the transistor part includes, but are not limited to, a first thin film transistor TFT1, a second thin film transistor TFT2, and a third thin film transistor TFT3.

The first thin film transistor TFT1 includes a first active layer ACT1, a first gate electrode G1, a first electrode E1a, and a second electrode E1b.

The first active layer ACT1 includes a first semiconductor material. The first semiconductor material includes, but is not limited to, an oxide semiconductor, amorphous silicon, polysilicon, low-temperature polysilicon (LTPS), or the like. The first thin film transistor TFT1 may be a p-channel transistor or an n-channel transistor, but aspects of the present disclosure are not limited thereto.

The first electrode E1a is a source electrode or a drain electrode, and the second electrode E1b is the drain electrode or the source electrode, respectively. Hereinafter, for convenience of explanation, embodiments are described where the first electrode E1a is a first source electrode E1a, and the second electrode E1b is a first drain electrode E1b, but aspects of the present disclosure are not limited thereto.

The second thin film transistor TFT2 includes a second active layer ACT2, a second gate electrode G2, a third electrode E2a, and a fourth electrode E2b.

The second active layer ACT2 includes a second semiconductor material. The second semiconductor material includes, but is not limited to, oxide semiconductors, amorphous silicon, polysilicon, low-temperature polysilicon (LTPS), or the like. The second thin film transistor TFT2 may be a p-channel transistor or an n-channel transistor, but aspects of the present disclosure are not limited thereto.

The third electrode E2a is a source electrode or a drain electrode, and the fourth electrode E2b is the drain electrode or the source electrode, respectively. Hereinafter, for convenience of explanation, embodiments are described where the third electrode E2a is a second source electrode E2a, and the fourth electrode E2b is a second drain electrode E2b, but aspects of the present disclosure are not limited thereto.

The third thin film transistor TFT3 includes a third active layer ACT3, a third gate electrode G3, a fifth electrode E3a, and a sixth electrode E3b.

The third active layer ACT3 includes a third semiconductor material. The third semiconductor material includes, but is not limited to, oxide semiconductors, amorphous silicon, polysilicon, low-temperature polysilicon (LTPS), or the like. The third thin film transistor TFT3 may be a p-channel transistor or an n-channel transistor, but aspects of the present disclosure are not limited thereto.

The fifth electrode E3a is a source electrode or a drain electrode, and the sixth electrode E3b is the drain electrode or the source electrode, respectively. Hereinafter, for convenience of explanation, embodiments are described where the fifth electrode E3a is a third source electrode E3a, and the sixth electrode E3b is a third drain electrode E3b, but aspects of the present disclosure are not limited thereto.

The types of respective semiconductor materials of the first active layer ACT1 of the first thin film transistor TFT1, the second active layer ACT2 of the second thin film transistor TFT2, and the third active layer ACT3 of the third thin film transistor TFT3 are as follows.

For example, each of the first active layer ACT1 of the first thin film transistor TFT1, the second active layer ACT2 of the second thin film transistor TFT2, and the third active layer ACT3 of the third thin film transistor TFT3 includes an oxide semiconductor material, but aspects of the present disclosure are not limited thereto. For example, each of the first active layer ACT1 of the first thin film transistor TFT1, the second active layer ACT2 of the second thin film transistor TFT2, and the third active layer ACT3 of the third thin film transistor TFT3 includes a low-temperature polysilicon semiconductor material, but aspects of the present disclosure are not limited thereto.

For example, all transistors included in each subpixel SP are implemented as the first thin film transistor TFT1. For example, all transistors included in each subpixel SP are implemented as the second thin film transistor TFT2. For example, all transistors included in each subpixel SP are implemented as the third thin film transistor TFT3. One or more of the transistors included in each subpixel SP are implemented as the first thin film transistor TFT1, and the remaining one or more of the transistors are implemented as the second thin film transistor TFT2 and the third thin film transistor TFT3. For example, each subpixel SP includes at least one first thin film transistor TFT1, at least one second thin film transistor TFT2, and at least one third thin film transistor TFT3.

In the following examples, one or more of the transistors included in each subpixel SP are implemented as the first thin film transistor TFT1, and the remaining one or more of the transistors are implemented as the second thin film transistor TFT2 and the third thin film transistor TFT3.

For example, in each subpixel SP, a driving transistor DT is implemented as the first thin film transistor TFT1, and the remaining one or more of the transistors (e.g., a scan transistor ST, an emission control transistor, and/or the like) are implemented as at least one of the second thin film transistor TFT2 and the third thin film transistor TFT3.

The first thin film transistor TFT1 connected to a first pixel electrode PE1 of a first light emitting element ED1 is a driving transistor DT or a transistor other than the driving transistor DT, depending on configuration of a corresponding subpixel circuit SPC. For example, in FIG. 5, the first thin film transistor TFT1 connected to the first pixel electrode PE1 of the first light emitting element ED1 is an emission control transistor connected between the driving transistor DT and the first light emitting element ED1.

The insulating layers (503, 504, 505, 506, 507, 508, 509, and 510) are disposed on the substrate 111 as follows. A first buffer layer is disposed on the substrate 111. The first buffer layer 503, 504 may be in the form of a single layer or a multilayer stack, but aspects of the present disclosure are not limited thereto. When the first buffer layer 503, 504 is in the form of a multilayer stack, the first buffer layer 503, 504 includes a first lower buffer layer 503 and a first upper buffer layer 504, but aspects of the present disclosure are not limited thereto.

A first gate insulating layer 505 and a first interlayer insulating layer 506 are disposed on the first buffer layer 503, 504.

The first gate insulating layer 505 is disposed on the third active layer ACT3 of the third thin film transistor TFT3. The third gate electrode G3 of the third thin film transistor TFT3 is disposed on the first gate insulating layer 505, but aspects of the present disclosure are not limited thereto.

The first interlayer insulating layer 506 is disposed on the third gate electrode G3 of the third thin film transistor TFT3. A metal layer in which the third gate electrode G3 of the third thin film transistor TFT3 is disposed may be referred to as a first gate metal layer, but aspects of the present disclosure are not limited thereto.

The third active layer ACT3 of the third thin film transistor TFT3 is disposed on the first buffer layer 503, 504. The third active layer ACT3 includes a channel region in which a channel is formed, a source connection region on one side of the channel region, and a drain connection region on the other side of the channel region, but aspects of the present disclosure are not limited thereto.

A second buffer layer 507, 508 is disposed on the first interlayer insulating layer 506. The second buffer layer may be in the form of a single layer or a multilayer stack, but aspects of the present disclosure are not limited thereto. When the second buffer layer 507, 508 is in the form of a multilayer stack, the second buffer layer includes a second lower buffer layer 507 and a second upper buffer layer 508, but aspects of the present disclosure are not limited thereto.

A second gate insulating layer 509 and a second interlayer insulating layer 510 are disposed on the second buffer layer 507, 508.

The second gate insulating layer 509 is disposed on the first active layer ACT1 of the first thin film transistor TFT1 and the second active layer ACT2 of the second thin film transistor TFT2. The first gate electrode G1 of the first thin film transistor TFT1 and the second gate electrode G2 of the second thin film transistor TFT2 are disposed on the second gate insulating layer 509, but aspects of the present disclosure are not limited thereto.

The second interlayer insulating layer 510 is disposed on the first gate electrode G1 of the first thin film transistor TFT1 and the second gate electrode G2 of the second thin film transistor TFT2. The first gate electrode G1 of the first thin film transistor TFT1 and the second gate electrode G2 of the second thin film transistor TFT2 may be referred to as a second gate metal layer, but aspects of the present disclosure are not limited thereto.

The first source electrode E1a and the first drain electrode E1b of the first thin film transistor TFT1 are connected to the source connection region and the drain connection region of the first active layer ACT1, respectively, through holes in the second interlayer insulating layer 510 and the second gate insulating layer 509.

The second source electrode E2a and the second drain electrode E2b of the second thin film transistor TFT2 are connected to the source connection region and the drain connection region of the second active layer ACT2, respectively, through holes in the second interlayer insulating layer 510 and the second gate insulating layer 509.

The third source electrode E3a and the third drain electrode E3b of the third thin film transistor TFT3 are connected to the source connection region and the drain connection region of the third active layer ACT3, respectively, through holes in the second interlayer insulating layer 510, the second gate insulating layer 509, the second buffer layer 507, 508, the first interlayer insulating layer 506, and the first gate insulating layer 505, but aspects of the present disclosure are not limited thereto.

The first source electrode E1a and the first drain electrode E1b of the first thin film transistor TFT1, the second source electrode E2a and the second drain electrode E2b of the second thin film transistor TFT2, and the third source electrode E3a and the third drain electrode E3b of the third thin film transistor TFT3 include a first source-drain metal and are disposed in a first source-drain metal layer.

The storage capacitor Cst is formed by a first capacitor electrode CAPE1 and a second capacitor electrode CAPE2. In one or more aspects, the storage capacitor Cst is formed by three or more capacitor electrodes. The storage capacitor Cst may also be in the form of two or more capacitors connected in parallel.

For example, each of the first capacitor electrode CAPE1 and the second capacitor electrode CAPE2 are disposed on various metal layers disposed in the display panel 110, but aspects of the present disclosure are not limited thereto.

The first capacitor electrode CAPE1 includes the same first gate metal as the third gate electrode G3 of the third thin film transistor TFT3 disposed on the first gate insulating layer 505, and is disposed in the first gate metal layer, but aspects of the present disclosure are not limited thereto. The second capacitor electrode CAPE2 is disposed on the first interlayer insulating layer 506, but aspects of the present disclosure are not limited thereto.

The transistor part further includes a first shield pattern BSM1 disposed on the substrate 111. The first shield pattern BSM1 overlaps with the first active layer ACT1 of the first thin film transistor TFT1. The first shield pattern BSM1 is disposed under the first active layer ACT1 of the first thin film transistor TFT1. The first shield pattern BSM1 is disposed in a metal layer between the first interlayer insulating layer 506 and the second buffer layer 507, 508, or is disposed between the second lower buffer layer 507 and the second upper buffer layer 508. However, aspects of the present disclosure are not limited thereto.

The transistor part further includes a second shield pattern BSM2 disposed on the substrate 111. The second shield pattern BSM2 overlaps with the second active layer ACT2 of the second thin film transistor TFT2. The second shield pattern BSM2 is disposed under the second active layer ACT2 of the second thin film transistor TFT2. The second shield pattern BSM2 is disposed in a metal layer between the first gate insulating layer 505 and the first interlayer insulating layer 506. The second shield pattern BSM2 is disposed in the same metal layer as the first capacitor CAPE1, but aspects of the present disclosure are not limited thereto. The second shield pattern BSM2 is disposed in the same first gate metal layer as the third gate electrode G3 of the third thin film transistor TFT3, but aspects of the present disclosure are not limited thereto.

The transistor part further includes a third shield pattern BSM3 disposed on the substrate 111. The third shield pattern BSM3 overlaps with the third active layer ACT3 of the third thin film transistor TFT3. The third shield pattern BSM3 is disposed under the third active layer ACT3 of the third thin film transistor TFT3. The third shield pattern BSM3 is disposed between the substrate 111 and the first buffer layer 503, 504, or is disposed between the first lower buffer layer 503 and the first upper buffer layer 504. However, aspects of the present disclosure are not limited thereto.

A planarization layer 520 is disposed on the first thin film transistor TFT1, the second thin film transistor TFT2, and the third thin film transistor TFT3, and is disposed under the first light emitting element ED1. The planarization layer 520 may be an organic insulating layer including an organic insulating material, but aspects of the present disclosure are not limited thereto.

The planarization layer 520 is in the form of a single layer. The planarization layer 520 includes two layers. The planarization layer 520 includes three or more layers, but aspects of the present disclosure are not limited thereto.

The planarization layer 520 including three or more layers includes a lower planarization layer 521, an intermediate planarization layer 522, and an upper planarization layer 523 in a sequential layer stack, but aspects of the present disclosure are not limited thereto. Hereinafter, for convenience of description, the planarization layer 520 may be expressed as a first planarization layer 520, but aspects of the present disclosure are not limited thereto.

The lower planarization layer 521 is disposed on the first source electrode E1a and the first drain electrode E1b of the first thin film transistor TFT1, the second source electrode E2a and the second drain electrode E2b of the second thin film transistor TFT2, and the third source electrode E3a and the third drain electrode E3b of the third thin film transistor TFT3. The lower planarization layer 521 is disposed on the first thin film transistor TFT1, the second thin film transistor TFT2, and the third thin film transistor TFT3. The lower planarization layer 521 is disposed such that it covers all of the first thin film transistor TFT1, the second thin film transistor TFT2, and the third thin film transistor TFT3, but aspects of the present disclosure are not limited thereto.

A first connection electrode RE1 is disposed on the lower planarization layer 521. The first connection electrode RE1 electrically interconnects the first source electrode E1a of the first thin film transistor TFT1 and the first pixel electrode PE1 of the first light emitting element ED1, but aspects of the present disclosure are not limited thereto.

The light emitting element part includes the first light emitting element ED1 that is disposed on the upper planarization layer 523. The first light emitting element ED1 may also be formed more generally on the first planarization layer 520. The first light emitting element ED1 includes a first pixel electrode PE1, a first intermediate layer EL1, and a common electrode CE1. A light emitting area of the first light emitting element ED1 is formed by an area where the first pixel electrode PE1, the first intermediate layer EL1, and the common electrode CE1 overlap with and contact each other.

The first pixel electrode PE1 is disposed on the upper planarization layer 523. The first pixel electrode PE1 is disposed on the first planarization layer 520. The first pixel electrode PE1 is electrically connected to the first connection electrode RE1 through holes in the intermediate planarization layer 522 and the upper planarization layer 523, but aspects of the present disclosure are not limited thereto.

The first planarization layer 520 includes an opening H2. The opening H2 may specifically be in and through a portion of the upper planarization layer 523 in embodiments where the first planarization layer 520 is a multi-layer structure. The first planarization layer 520 further includes a black bank 530 disposed in the opening H2 and the first pixel electrode PE1. The black bank 530 exposes a portion of the first pixel electrode PE1 to form a light emitting area. The black bank 530 overlaps with a portion of the first pixel electrode PE1.

The black bank 530 includes a material including a black pigment, or an organic material including a benzocyclobutene resin, a polyimide resin, an acrylic resin, a photosensitive polymer, or the like. However, aspects of the present disclosure are not limited thereto. The black bank 530 includes a material including a black pigment or a black dye, or the like. When the black bank 530 includes a material including a black pigment or a black dye, the luminance of the display device 100 can be further improved because light from the outside or light reflected from the outside can be blocked. However, aspects of the present disclosure are not limited thereto.

The black bank 530 includes, but is not limited to, a first black bank 531 and a second black bank 532. The first black bank 531 is located in the opening H2 of the first planarization layer 520 and has a groove 531-G depressed downwardly from the upper surface of the first black bank 531, but aspects of the present disclosure are not limited thereto. In more detail, the opening H2 through the upper planarization layer 523 has sloped sides such that the first black back 531 likewise has sloped sides. The first black bank 531 includes an upper surface 531-U that may be a top or uppermost surface of the first black bank 531. The first black bank overlaps and is in direct contact with the upper planarization layer 523 on opposite sides of the opening H2. The groove 531-G in the upper surface 531-U of the first black bank 531 is in the form of a downwardly convex depression in the upper surface 531-U such that the first black bank 531 has a concave shape at the location of the groove 531-G. Thus, the upper surface 531-U of the first black bank 531 has a curved surface corresponding to the location of the groove 531-G. The ends of the curve in the upper surface 531-U may be aligned with, or overlap, the sloped side surfaces of the upper planarization layer 523. For example, an interface where the curved portion of the upper surface 531-U meets a flat and planar portion of the upper surface 531-U (i.e., a location where the curved surface terminates) may be aligned with lower terminal ends of the sloped side surfaces of the upper planarization layer 523.

The second black bank 532 is located on the first planarization layer 520, and specifically directly on the upper planarization layer 523 where the planarization layer 520 is a multi-layer structure. The second black bank 532 further includes a hole 532_H, but aspects of the present disclosure are not limited thereto. The second black bank 532 overlaps and is in direct contact with at least a portion of the first pixel electrode PE1 and a first connection pattern CP1 described further below. The second black bank 532 is spaced from the first black bank 531 across the first light emitting element ED1 or the first light emitting element ED1 is between the black banks 531, 532.

For example, a non-black bank 540 is disposed on the first pixel electrode PE1 and the black bank 530 and in some embodiments, in direct contact with such features in a multi-layer stack. The non-black bank 540 is a transparent bank in some embodiments, but aspects of the present disclosure are not limited thereto.

The non-black bank 540 overlaps with the opening H2 of the first planarization layer 520 and fills the groove 531-G in the first black bank 531. The non-black bank 540 may be disposed on and in direct contact with the first intermediate layer EL1 of the first light emitting element ED1. The non-black bank 540 includes a first trench TRC1 corresponding to the groove 531-G of the first black bank 531, but aspects of the present disclosure are not limited thereto. The first trench TRC1 is aligned with and corresponds to the groove 531-G of the first black bank 531 in some embodiments. The first trench TRC1 provides an advantage in the display device 100 of reducing a defect due to leakage current.

In an embodiment, a spacer 533 is disposed on the non-black bank 540. The spacer 531 overlaps with the second black bank 532, but aspects of the present disclosure are not limited thereto. In an embodiment, the spacer 533 is positioned in direct contact with a top or upper surface of the non-black bank 540 over the second black bank 532 such that the spacer 533 is between the first intermediate layer EL1 and the non-black bank 540 on top of the second black bank 532.

The first intermediate layer EL1 of the first light emitting element ED1 are disposed on a portion of the first pixel electrode PE1 and the non-black bank 540, and the common electrode CE1 is disposed on the first intermediate layer EL1. However, aspects of the present disclosure are not limited thereto.

In one or more aspects, the display panel 110 further includes a common voltage line to which a common voltage is applied, and further includes the first connection pattern CP1 for electrically interconnecting the common voltage line and the common electrode CE1. The first connection pattern CP1 overlaps with the hole 532_H of the second black bank 532 and is disposed on the first planarization layer 520 in the hole 532_H. Further, the first connection pattern CP1 includes the same material as the first pixel electrode PE1 in some embodiments. However, aspects of the present disclosure are not limited thereto.

The encapsulation part is disposed on the light emitting element part, and is located on the common electrode CE1. The encapsulation part includes an encapsulation layer 200 disposed on the common electrode CE1.

The encapsulation layer 200 can prevent moisture or oxygen from penetrating into the first light emitting element ED1. The encapsulating layer 200 can prevent moisture or oxygen from penetrating into an organic material included in the first intermediate layer EL1 of the first light emitting element ED1. The encapsulation layer 200 may be in the form of a single layer or includes multiple layers, but aspects of the present disclosure are not limited thereto.

The encapsulation layer 200 includes a first encapsulation layer 550, a second encapsulation layer 551, and a third encapsulation layer 552, but aspects of the present disclosure are not limited thereto. The first encapsulation layer 550 and the third encapsulation layer 552 includes an inorganic encapsulation layer, and the second encapsulation layer 551 includes an organic encapsulation layer, but aspects of the present disclosure are not limited thereto.

In one or more aspects, a touch sensor is embedded in the display panel 110. In this configuration, the display panel 110 includes a touch sensor layer 560 disposed on the encapsulation layer 200 and containing the touch sensor. The touch sensor layer 560 includes a plurality of touch electrodes serving as the touch sensor, and includes at least one touch metal layer for forming the plurality of touch electrodes.

For example, to form the plurality of touch electrodes, the touch sensor layer 560 includes a first touch metal layer 561 in which at least one first touch metal TM1 is disposed, and a second touch metal layer 564 in which at least one second touch metal TM2 is disposed. In this implementation, the touch sensor layer 560 further includes a touch buffer layer 562 and a touch interlayer insulation layer 563 disposed between the first touch metal layer 561 and the second touch metal layer 564, but aspects of the present disclosure are not limited thereto.

For example, when the first touch metal layer 561 is a bridge metal layer, and the second touch metal layer 564 is a sensor metal layer, second touch metals TM2 serving as the touch sensor are electrically connected through at least one first touch metal TM1, which is the bridge metal. The second touch metals TM2 are electrically connected to the at least one first touch metal TM1 to form one touch electrode TE.

In one or more aspects, the display panel 110 further includes a black matrix 570 having at least one first opening 570_H1 on the touch sensor layer 560. At least one of the first touch metal TM1 and the second touch metal TM2 overlap with the black matrix 570, but aspects of the present disclosure are not limited thereto.

In one or more aspects, the display panel 110 further includes a first color filter CF1 disposed on the black matrix 570 and overlapping with the first opening 570_H1. The display panel 110 also includes an overcoat layer 580 disposed on the first color filter CF1. Unless the context dictates otherwise, the layer stack of the display panel 110 illustrated in FIGS. 5-8 is representative of the actual layers of the stack such that various layers are disposed in sequential order and/or in direct contact with each other in the manner shown in the accompanying drawings, even if not expressly described herein.

A situation can occur in display panels where light that is emitted from the light emitting element reaches the encapsulation layer and is totally reflected back into the display panel. The reflected light may then be absorbed by the black bank or flow into the transistor part instead of exiting the display panel, as intended. This is illustrated in FIG. 5 with dashed arrows 534 representing light that is reflected by the encapsulation part into the display panel instead of exiting the display panel. As a result, the light extraction efficiency may be reduced. Unless otherwise noted, the term “light extraction” means light that is generated by a light emitting element that is extracted or directed outside of the display panel or caused to exit the display panel. Thus, the term “light extraction efficiency” refers to the percentage or amount of light that exits the display panel relative to the total light generated by the light emitting element. A light extraction efficiency of 90% therefore means that 90% of the total light emitting by the light emitting element exits the display panel while the remaining 10% is reflected back into the display panel and/or is absorbed in the display panel.

The concepts of the disclosure address this issue by providing a structure of the display panel 110 capable of increasing such light extraction efficiency by causing light absorbed by the black bank 530 or flowing into the inside of the transistor part to be extracted outside of the display panel 110 or otherwise allowed to exit the display panel 110, as described further in the following embodiments.

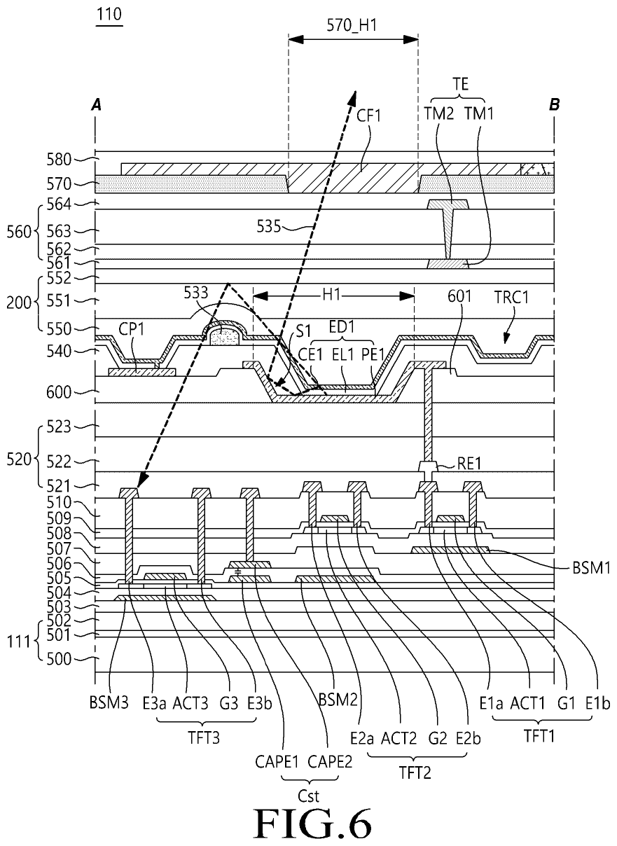

Referring to FIG. 6, and with continuing reference to FIG. 5, in one or more example embodiments, the display panel 110 further includes a second planarization layer 600 including a first hole H1 such that the second planarization layer 600 has an inner surface surrounding the first hole H1 that is an first inclined surface S1. Discussion of features of the display panel 110 of FIG. 6 that are equal, substantially equal, or similar to the features described with reference to FIG. 5 are omitted for brevit.

The first pixel electrode PE1 of the first light emitting element ED1 is disposed on the first planarization layer 520 in the first hole H1, and extends along the first inclined surface S1 to an upper surface of the second planarization layer 600. However, aspects of the present disclosure are not limited thereto.

The non-black bank 540 is disposed on the first pixel electrode PE1 and the second planarization layer 600. The non-black bank 540 is a transparent bank, but aspects of the present disclosure are not limited thereto.

The non-black bank 540 includes a first trench TRC1 on one side thereof, but aspects of the present disclosure are not limited thereto. The first trench TRC1 provides an advantage of reducing a defect due to leakage current.

The non-black bank 540 may further include the spacer 533 on the other side thereof, but aspects of the present disclosure are not limited thereto.

The first intermediate layer EL1 of the first light emitting element ED1 is disposed on a portion of the first pixel electrode PE1 and the non-black bank 540, and the common electrode CE1 is disposed on the first intermediate layer EL1. However, aspects of the present disclosure are not limited thereto.

In one or more aspects, the display panel 110 further includes a common voltage line to which a common voltage is applied, and a first connection pattern CP1 for electrically interconnecting the common voltage line and the common electrode CE1. The first connection pattern CP1 is disposed on the second planarization layer 600 and includes the same material as the first pixel electrode PE1, but aspects of the present disclosure are not limited thereto.

The second planarization layer 600 is positioned on top of and in direct contact with the upper planarization layer 523 and/or the first planarization layer 520. The first light emitting element ED1 is formed in the hole H1 in the second planarization layer 600. Further, the display panel 110 of FIG. 6 may omit the black bank 530 (i.e., the first and second black banks 531, 532) and instead include the second planarization layer 600. In an embodiment, the display panel 110 of FIG. 6 does not include a black bank or any black banks. Accordingly, the trench TRC1 extends over a portion of the second planarization layer 600 instead of over the first black bank 531. The second planarization layer 600 may have a varying thickness across the second planarization layer 600 in some embodiments. For example, the second planarization layer 600 includes a stepped configuration with a ridge 601 that increases the thickness of the second planarization layer 600 in at least some areas of the second planarization layer 600 relative to other areas. The ridge 601 is formed around the first hole H1 such that the second planarization layer 600 has an area of increased thickness around the first hole H1 relative to any other area, region, or portion of the second planarization layer 600. The ridge 601 and overall stepped configuration of the second planarization layer 600 at the location of the first hole H1 increases the length of the first inclined surface S1 to assist with extracting additional light, as described below.

In the display panel 110 of FIG. 6, light emitted from the first light emitting element ED1 is reflected on the first inclined surface S1 of the second planarization layer 600 and caused to exit the display panel 110, as shown by dashed arrow 535. Thereby, the light extraction efficiency of the display device 100 can be improved. However, a situation where the first light reaching the encapsulation layer 200 is reflected totally and then flows into the inside of the transistor part may still occur, as described above, and this situation may cause the light extraction efficiency of the display panel 100 to be reduced. Thus, the display panel 110 of FIG. 6 is an improvement over prior solutions, but the disclosure contemplates additional solutions to further improve light extraction efficiency.

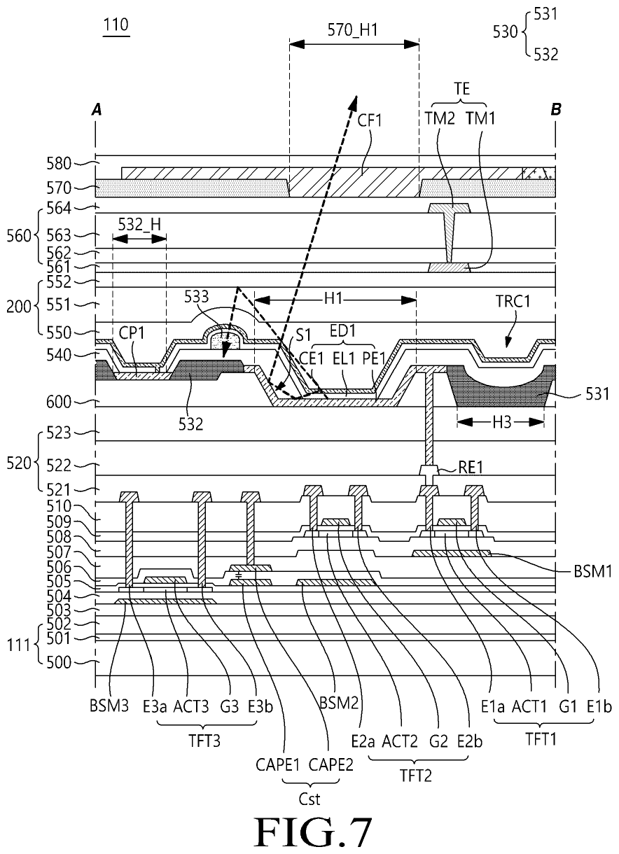

Referring to FIG. 7, and with continuing reference to FIG. 5 and FIG. 6, in one or more example embodiments, the display panel 110 includes the second planarization layer 600. The second planarization layer 600 includes the first hole H1 described above having an inner surface including a first inclined surface S1, and a second hole H3 different from the first hole H1. Repetitive features of FIG. 7 relative to the above description are omitted for simplicity.

The first pixel electrode PE1 of the first light emitting element ED1 is disposed on the first planarization layer 520 in the first hole H1, and extends along the first inclined surface S1 to an upper surface of the second planarization layer 600. However, aspects of the present disclosure are not limited thereto.

A black bank 530 is disposed in the second hole H3 and on the second planarization layer 600, but aspects of the present disclosure are not limited thereto. The black bank 530 includes a first black bank 531 and a second black bank 532, but aspects of the present disclosure are not limited thereto. In the display panel 110 of FIG. 7, the second planarization layer 600 includes the second hole H3 instead of the first planarization layer 520 including the second hole H2. The second hole H3 of FIG. 7 is otherwise similar to the second hole H2 and will not be described further.

The first black bank 531 is located in the second hole H2. and is otherwise similar to the first black bank 531 described above. The second black bank 532 is disposed on the second planarization layer 600 and includes a hole 532_H, but aspects of the present disclosure are not limited thereto.

The non-black bank 540 is disposed on the first black bank 531, the second black bank 532, and the first pixel electrode PE1, but aspects of the present disclosure are not limited thereto. The non-black bank 540 may be a transparent bank, but aspects of the present disclosure are not limited thereto.

The non-black bank 540 includes a first trench TRC1 overlapping with the second hole H3 and corresponding to the groove of the first black bank 531. The first trench TRC1 provides an advantage of reducing a defect due to leakage current.

A spacer 533 is disposed on the non-black bank 540. The spacer 533 overlaps with the second black bank 532, but aspects of the present disclosure are not limited thereto.

The first intermediate layer EL1 of the first light emitting element ED1 is disposed on a portion of the first pixel electrode PE1 and the non-black bank 540, and the common electrode CE1 is disposed on the first intermediate layer EL1. However, aspects of the present disclosure are not limited thereto.

As described above with reference to FIG. 6, light emitted from the first light emitting element ED1 can be reflected on the first inclined surface S1 and caused to exit the display panel 110, thereby improving light extraction efficiency.

However, the display panel 110 of FIG. 7 includes the black bank 530 such that instead of light entering the transistor part as in FIG. 6, light reaching the encapsulation layer 200 that is reflected by the encapsulation layer 200 is absorbed by the black bank 530, thereby preventing optimization of the light extraction efficiency. Further, a viewing angle characteristic may be reduced due to external light entering display panel 110. Accordingly, FIG. 7 likewise provides a solution to improving light extraction efficiency in an embodiment of the display panel 110 that includes the black bank 530.

The present disclosure further contemplates embodiments of the display panel 110 where light absorbed by the black bank 530 or reaching the inside of the transistor part can be extracted outside of the display panel 110, and thereby, the light extraction efficiency of the display panel 110 can be increased and an improved viewing angle characteristic can be implemented. In other words, the following embodiments further optimize light extraction efficiency while also improving viewing angle characteristics over the solutions described with reference to FIG. 6 and FIG. 7.

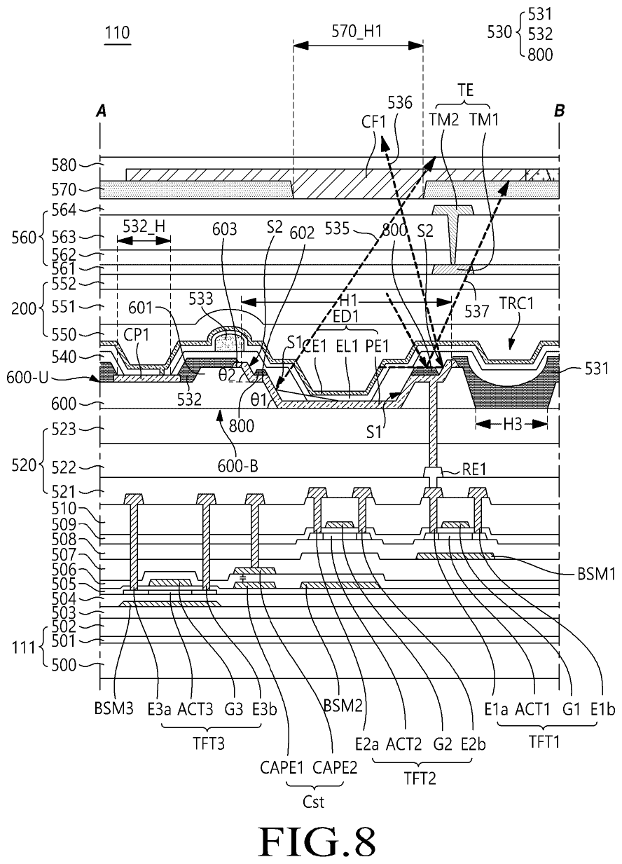

Referring to FIG. 8, with continuing reference to FIGS. 5-7, in one or more example embodiments, the second planarization layer 600 of the display panel 110 includes the first hole H1 having an inner surface including a first inclined surface S1 and a second inclined surface S2, and the second hole H3 different from the first hole H1. Repetitive features of FIG. 8 relative to the above description are omitted for simplicity.

The second planarization layer 600 of FIG. 8 has a different structure and arrangement than the other planarization layers described herein. The second planarization layer 600 includes the protrusion 601 that increases a thickness of a portion of the second planarization layer 600 in a stepped configuration, but the protrusion 601 is spaced from the first hole H1 instead of being located at the first hole H1 as described elsewhere. Thus, while the protrusion 601 still surrounds the first hole H1, the protrusion 601 defines a first ledge 602 and a second ledge 603. The first ledge 602 is a flat and planar area of the second planarization layer 600 that is between the protrusion 601 and the first hole H1. The second ledge 603 corresponds to a top surface of the protrusion 601. Such an arrangement creates the first and second inclined surfaces S1, S2 of the second planarization layer 600 that define the first hole H1. The sidewalls of the second planarization layer 600 that form the first hole H1 therefore have a two-step configuration and a width of the first hole H1 varies across the first hole H1. Specifically, a lower or bottommost part of the first hole H1 adjacent the first light emitting element ED1 has a width that is less than a width of the first hole H1 above the first ledge 602 as a result of the protrusion 601 being spaced or offset from an interface between the first hole H1 and the second planarization layer 600 at the first light emitting element ED1. In other words, in an embodiment, the protrusion 601 has a trapezoidal cross section that is offset from an edge of the second planarization layer 600 where a major portion or majority of the first hole H1 extends through the second planarization layer 600 to create the two-stepped configuration shown in FIG. 8. The benefits of the first and second inclined surfaces S1, S2 are described further below.

The first pixel electrode PE1 of the first light emitting element ED1 is disposed on the first planarization layer 520 in the first hole H1, and extends along the first inclined surface S1 and the second inclined surface S2 to an upper surface 600-U of the second planarization layer 600. However, aspects of the present disclosure are not limited thereto.

A first angle θ1 is formed by the first inclined surface S1 and a back, bottom, or rear surface 600-B of the second planarization layer 600, but aspects of the present disclosure are not limited thereto. Further, a second angle θ2 is formed by the second inclined surface S2 and the back, bottom, or rear surface 600-B of the second planarization layer 600, but aspects of the present disclosure are not limited thereto. The first angle θ1 is preferably less than the second angle θ2 to provide the benefits described herein, but aspects of the present disclosure are not limited thereto. In general, the angles θ1, θ2 may generally be selected and may be the same or different than each other, such as the first angle θ1 being greater than the second angle θ2.

A black bank 530 is disposed in the second hole H3 and on the second planarization layer 600, but aspects of the present disclosure are not limited thereto. The black bank 530 includes, but is not limited to, a first black bank 531, a second black bank 532, and a third black bank 800.

The first black bank 531 is located in the second hole H3 and has groove depressed downwardly from the upper surface of the first black bank 531, as described elsewhere. The second black bank 532 is disposed on the second planarization layer 600 and includes a hole 532_H corresponding to the first connection pattern CP1, but aspects of the present disclosure are not limited thereto. The third black bank 800 is located between the first inclined surface S1 and the second inclined surface S2, but aspects of the present disclosure are not limited thereto. Specifically, the third black bank 800 is located on the first ledge 602 between the protrusion 601 and the first light emitting element ED1 located in the first hole H1. Accordingly, the first ledge 602 and the arrangement of the protrusion 601 also provides a flat support surface and/or space for formation of the third black bank 800 that provides the benefits described herein.

A non-black bank 540 may be located on the first black bank 531, the second black bank 532, the third black bank 800, and the first pixel electrode PE1, but aspects of the present disclosure are not limited thereto. The non-black bank 540 may be a transparent bank, but aspects of the present disclosure are not limited thereto.

The non-black bank 540 includes a first trench TRC1 overlapping with the second hole H3 and corresponding to the groove depressed from the upper surface of the first black bank 531, but aspects of the present disclosure are not limited thereto. The first trench TRC1 provides an advantage of reducing a defect due to leakage current.

A spacer 533 is disposed on the non-black bank 540. The spacer 533 overlaps with the second black bank 532, but aspects of the present disclosure are not limited thereto.

The first intermediate layer EL1 of the first light emitting element ED1 is disposed on a portion of the first pixel electrode PE1 and the non-black bank 540, and the common electrode CE1 is disposed on the first intermediate layer EL1. However, aspects of the present disclosure are not limited thereto.

In the configuration of the display panel 110 according to FIG. 8, light emitted from the first light emitting element ED1 is reflected on the first inclined surface S1 and caused to exit the display panel 110, and thereby, the light extraction efficiency of the display panel 110 can be improved, similar to the display panels 110 of FIG. 6 and FIG. 7 described above and as shown with arrow 535 in FIG. 8.

Light that is emitted from the first light emitting element ED1 may be reflected totally by a common electrode CE1, and specifically from the back surface of the common electrode CE1. In such a situation, the light can be reflected on the first and/or second inclined surfaces S1, S2 and caused to exit the display panel 110, as shown by arrow 536. Thereby, the light extraction efficiency of the display panel 110 can be improved.

In addition, external light entering the display panel 110 can be absorbed by the third black bank 800. In another example, in a situation where external light entering the display panel 110 is reflected by the third black bank 800, the light can be absorbed by a black matrix 570. The absorption and/or reflection of light by the third black bank 800 is represented schematically by arrow 537 in FIG. 8. Thereby, reflection sensitivity can be improved, and the viewing angle of the display panel 110 can be improved or increased. Accordingly, offsetting the protrusion 601 of the second planarization layer 600 from the first hole H1 forms the first ledge 602 that enables formation of an additional black bank and two inclined surfaces to provide substantial improvements in light extraction efficiency, reflection sensitivity, and viewing angle characteristics.

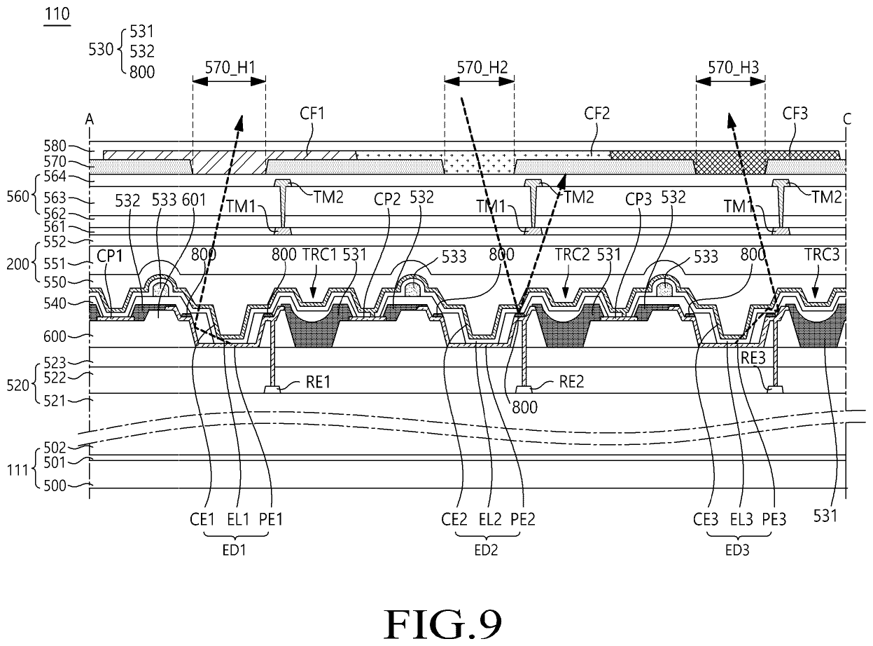

FIG. 9 is an example cross-sectional view of the display panel 110 taken along line A-C of FIG. 4 according to aspects of the present disclosure. The concepts shown in FIG. 9 are discussed with continuing reference to FIGS. 5 to 8, and repetitive description is omitted.

Referring to FIGS. 8 and 9, in one or more example embodiments, the display panel 110 includes a substrate 111, a planarization layer, a light emitting element part, and an encapsulation part, but aspects of the present disclosure are not limited thereto.

The substrate 111 is in the form of a single layer or a multilayer stack. In an example where the substrate 111 includes a multilayer stack, the substrate 111 includes a first substrate 500, an intermediate substrate layer 501, and a second substrate 502. The intermediate substrate layer 501 may be located between the first substrate 500 and the second substrate 502.

The planarization layer includes a first planarization layer 520 and a second planarization layer 600. The first planarization layer 520 includes, but is not limited to, a lower planarization layer 521, an intermediate planarization layer 522, and an upper planarization layer 523. The second planarization layer 600 may be similar to any of the second planarization layers 600 described herein.

In one or more aspects, insulating layers included in the transistor part are disposed between the substrate 111 and the first planarization layer 520, but aspects of the present disclosure are not limited thereto.

The light emitting element part includes a first light emitting element ED1, a second light emitting element ED2, and a third light emitting element ED3 disposed on the first planarization layer 520. However, aspects of the present disclosure are not limited thereto. At least one of the first light emitting element ED1, the second light emitting element ED2, and the third light emitting element ED3 may emit light of a color different from the remaining one or more light emitting elements, but aspects of the present disclosure are not limited thereto.

The first light emitting element ED1 includes a first pixel electrode PE1, a first intermediate layer EL1, and a common electrode CE1. A light emitting area of the first light emitting element ED1 is formed by an area where the first pixel electrode PE1, the first intermediate layer EL1, and the common electrode CE1 overlap with and contact each other, but aspects of the present disclosure are not limited thereto.

The second light emitting element ED2 includes a second pixel electrode PE2, a second intermediate layer EL2, and a common electrode CE2. A light emitting area of the second light emitting element ED2 is formed by an area where the second pixel electrode PE2, the second intermediate layer EL2, and the common electrode CE2 overlap with and contact each other, but aspects of the present disclosure are not limited thereto.

The third light emitting element ED3 includes a third pixel electrode PE3, a third intermediate layer EL3, and a common electrode CE3. A light emitting area of the third light emitting element ED3 is formed by an area where the third pixel electrode PE3, the third intermediate layer EL3, and the common electrode CE3 overlap with and contact each other, but aspects of the present disclosure are not limited thereto.

The first light emitting element ED1 can emit, but not limited to, a first light. The second light emitting element ED2 can emit, but not limited to, a second light different from the first light. The third light emitting element ED2 can emit, but not limited to, a third light different from the first light and the second light.

A first connection electrode RE1 is disposed on the lower planarization layer 521. Although not shown in FIG. 9, in FIGS. 5 to 8, the first connection electrode RE1 electrically interconnects a first source electrode E1a of a first thin film transistor TFT1 of the transistor part and the first pixel electrode PE1 of the first light emitting element ED1, but aspects of the present disclosure are not limited thereto. The first pixel electrode PE1 may be electrically connected to the first connection electrode RE1 through a hole in the intermediate planarization layer 522 and the upper planarization layer 523, but aspects of the present disclosure are not limited thereto.

A second connection electrode RE2 is disposed on the lower planarization layer 521. Although not shown in FIG. 9, the second connection electrode RE2 electrically interconnects a source electrode of a thin film transistor of the transistor part and the second pixel electrode PE2 of the second light emitting element ED2, but aspects of the present disclosure are not limited thereto. The second pixel electrode PE2 is electrically connected to the second connection electrode RE2 through holes in the intermediate planarization layer 522 and the upper planarization layer 523, but aspects of the present disclosure are not limited thereto.

A third connection electrode RE3 is disposed on the lower planarization layer 521. Although not shown in FIG. 9, the third connection electrode RE3 electrically interconnects a source electrode of a thin film transistor of the transistor part and the third pixel electrode PE3 of the third light emitting element ED3, but aspects of the present disclosure are not limited thereto. The third pixel electrode PE3 is electrically connected to the third connection electrode RE3 through holes in the intermediate planarization layer 522 and the upper planarization layer 523, but aspects of the present disclosure are not limited thereto.

A black bank 530 is disposed on the second planarization layer 600, but aspects of the present disclosure are not limited thereto. The black bank 530 includes, but is not limited to, a first black bank 531, a second black bank 532, and a third black bank 800.

The encapsulation part is disposed on the light emitting element part and be located on the common electrode (CE1, CE2, and CE3). The encapsulation part includes an encapsulation layer 200 disposed on the common electrode (CE1, CE2, and CE3). The encapsulation layer 200 can prevent moisture or oxygen from penetrating into the first light emitting element ED1, the second light emitting element ED2, and the third light emitting element ED3. The encapsulation layer 200 can prevent moisture or oxygen from penetrating into organic matter included in the first intermediate layer EL1, the second intermediate layer EL2, and the third intermediate layer EL3 of the first light emitting element ED1, the second light emitting element ED2, and the third light emitting element ED3. The encapsulation layer 200 may be in the form of a single layer or may include multiple layers, but aspects of the present disclosure are not limited thereto.

In one or more aspects, a touch sensor layer 560 is disposed on the encapsulation layer 200 and includes a touch sensor. The touch sensor layer 560 includes a plurality of touch electrodes serving as the touch sensor, and includes at least one touch metal layer for forming the plurality of touch electrodes.

For example, to form the plurality of touch electrodes, the touch sensor layer 560 includes a first touch metal layer 561 in which at least one first touch metal TM1 is disposed, and a second touch metal layer 564 in which at least one second touch metal TM2 is disposed. In this implementation, the touch sensor layer 560 may further include a touch buffer layer 562 and a touch interlayer insulation layer 563 disposed between the first touch metal layer 561 and the second touch metal layer 564, but aspects of the present disclosure are not limited thereto.

In one or more aspects, a black matrix 570 having a first opening 570_H1, a second opening 570_H2, and a third opening 570_H3 is disposed on the touch sensor layer 560. At least one of the first touch metal TM1 and the second touch metal TM2 may be overlapped with the black matrix 570, but aspects of the present disclosure are not limited thereto.

In one or more aspects, color filters including a first color filter CF1 overlapping with the first opening 570_H1, a second color filter CF2 overlapping with the second opening 570_H2, and a third color filter CF3 overlapping with the third opening 570_H3 are disposed on the black matrix 570, and an overcoat layer 580 is disposed on the color filters. The display panel 110 of FIG. 9 likewise includes the protrusion 601 of the second planarization layer 600 spaced from the edge of the second planarization layer 600 at the interface with the first hole H1, thus forming the first and second inclined surfaces S1, S2 shown in FIG. 8.

Referring to FIG. 8 and FIG. 9, first light emitted from the first light emitting element ED1 may be reflected on the first inclined surface S1 and caused to exit the display panel 110, and thereby, the light extraction efficiency of the display panel 110 can be improved.

Referring to FIG. 9, for example, external light entering the display panel 110 can be absorbed by the third black bank 800. In another example, in a situation where external light entering the display panel 110 is reflected by the third black bank 800, the light can be absorbed by the black matrix 570. Thereby, reflection sensitivity can be improved, and the viewing angle characteristic can be implemented.

Referring to FIG. 9, in a situation where third light emitted from the third light emitting element ED3 is totally reflected by a back surface of the common electrode CE3 the third light can be reflected on the first and/or second inclined surfaces S1, S2 and caused to exit the display panel 110, and thereby, the light extraction efficiency of the display panel 110 can be improved.

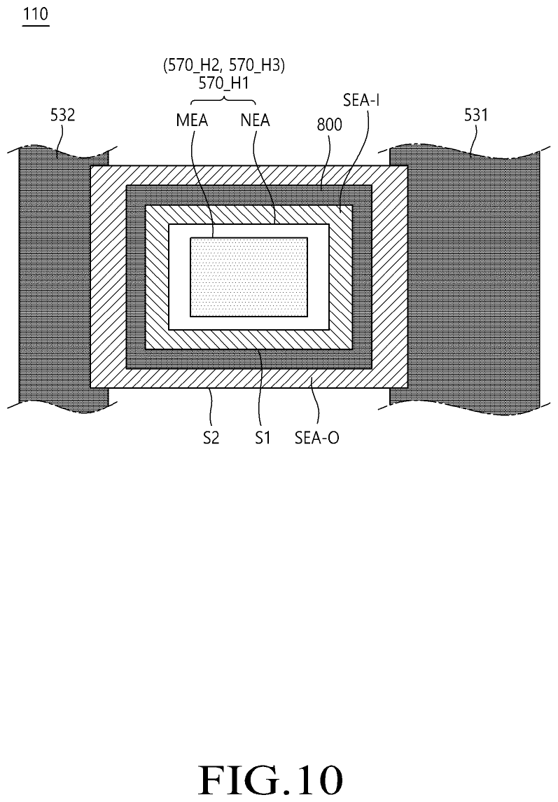

FIG. 10 is a plan view of an example light emitting area of the display panel 110 according to aspects of the present disclosure.

Referring to FIG. 10, when a subpixel of the display panel is viewed in the planar view, the third black bank 800 is disposed in a form surrounding at least one subpixel having a plurality of light emitting areas. However, aspects of the present disclosure are not limited thereto.

The third black bank 800 is located inside of the first hole H1 on the first ledge 602 shown in FIG. 8, which is disposed in the second planarization layer 600, and is disposed in a form surrounding an inner side surface of the first hole H1. However, aspects of the present disclosure are not limited thereto. In another example, the third black bank 800 is located between the first inclined surface S1 and the second inclined surface S2 of FIG. 8, but aspects of the present disclosure are not limited thereto.

For example, at least two light emitting areas and one non-light emitting area NEA is disposed inside of the third black bank 800, but aspects of the present disclosure are not limited thereto. The at least two light emitting areas disposed inside of the third black bank 800 correspond to a main light emitting area MEA and an area corresponding to the first inclined surface S1 serving as a light reflection area, respectively, but aspects of the present disclosure are not limited thereto. In other words, one of the light emitting areas is the main light emitting aera MEA corresponding to the light emitting element and a second one of the light emitting areas, among potentially others, is a light reflection area corresponding to light reflected from the first inclined surface S1. The light reflected from the first inclined surface S1 is designed as a supplemental emitting area SEA with the supplemental area inside of the third black bank 800 being designated as SEA-I.

The main light emitting area MEA and the non-light emitting area NEA overlap with at least one of the first opening 570_H1, the second opening 570_H2, and the third opening 570_H3 of the black matrix 570 of FIG. 9, but aspects of the present disclosure are not limited thereto.

The main light emitting area MEA may represent an area where the first pixel electrode PE1, the first intermediate layer EL1, and the common electrode CE1 of the first light emitting element ED1 overlap with each other in the first hole H1 of FIG. 8, but aspects of the present disclosure are not limited thereto. The light emitting area corresponding to the first inclined surface S1 may be formed by an area where first light emitted from the first light emitting element ED1 is reflected on the first inclined surface S1 of FIG. 8 and then caused to exit the display panel 110, but aspects of the present disclosure are not limited thereto.

The one non-light emitting area NEA includes a portion of an area where the first pixel electrode PE1 overlaps with the first planarization layer 520 except for the main light emitting area MEA in the first hole H1 of FIG. 8, but aspects of the present disclosure are not limited thereto.

For example, at least one light reflection area may be formed outside of the third black bank 800. The at least one light reflection area disposed outside of the third black bank 800 may correspond to the second inclined surface S2 (i.e., light reflected from the second inclined surface S2) and be disposed in a form surrounding the third black bank 800, but aspects of the present disclosure are not limited thereto. In another example, a light emitting area may be formed by an area where as first light emitted from the first light emitting element ED1 of FIG. 8 is reflected totally by the common electrode CE1, the first light is reflected from the back surface of the common electrode CE1, and the reflected first light is re-reflected on the second inclined surface S2 and caused to exit the display panel 110. However, aspects of the present disclosure are not limited thereto. The reflected light from the second inclined surface S2 is generally shown as an outer supplemental emitting area SEA-O outside of the third black bank 800.

A first side surface of the third black bank 800 is disposed to be spaced apart from the first black bank 531 by a first distance, and a second opposite side surface of the third black bank 800 is disposed to be spaced apart from the second black bank 532 by a second distance. However, aspects of the present disclosure are not limited thereto. A third light reflection area is formed in respective areas located between the third black bank 800 and each of the first black bank 531 and the second black bank 532 and spaced apart by the first distance and the second distance.

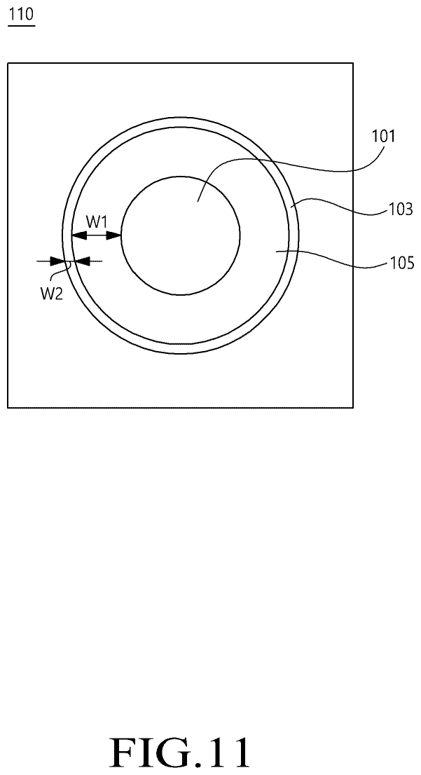

FIG. 11 is a plan view of an embodiment of a plurality of light emitting areas of the display panel 110. The display panel 110 includes a main light emitting area 101 and a secondary light emitting area 103. The main light emitting area 101 corresponds to light emitted through the hole 570_H1 from the first light emitting element ED1. The secondary light emitting area 103 corresponds to light that is not absorbed by the black matrix 570, but rather, passes through the black matrix 570, the first color filter CF1, and the overcoat layer 580. In other words, the black matrix 570 may not absorb all of the light emitting by the first light emitting element ED1 and at least some portion of the light emitted by the first light emitting element ED1 will pass through the black matrix 570 to form secondary light emitting area 103. The main light emitting area 101 has a larger size than the secondary light emitting area 103. In some embodiments, the light emitted in the second light emitting area 103 is similar to the light emitted in the first light emitting area 101. For example, the color of light emitted in the secondary light emitting area 103 is the same as the color of light emitted in the main light emitting area 101. A color coordinate of visible light emitted from the main light emitting area 101 may be the same or different from a color coordinate of the light emitted from the secondary light emitting area 103. Further, due to the difference in size between the emitting areas 101, 103, the amount of light emitted in each area may be different.

As shown in FIG. 11, the main light emitting area 101 is located centrally relative to the secondary light emitting area 103 in the plan view of the display panel 110. The secondary light emitting area 103 is concentric with respect to the main light emitting area 101. Further, the light emitting areas 101, 103 have a circular shape in some embodiments, but may also be any other selected shape, including without limitation rectangles and others. The secondary light emitting area 103 is spaced from the main light emitting area 101 by an intermediate area 105. The intermediate area 105 can be a light emitting area or a non-light emitting area in various embodiments. For example, the embodiments described above with respect to FIG. 10, the intermediate area 105 is the non-emitting area NEA. But for the embodiments described with respect to FIG. 5, the intermediate area 105 may be a further light emitting area such that the display panel 110 includes at least three light emitting areas 101, 103, 105. The intermediate area 105 is concentric with the main light emitting area 101 and the secondary light emitting area 103 and is positioned between the main and secondary light emitting areas 101. 103. Thus, the main light emitting area 101, the intermediate area 105, and the secondary light emitting area 103 are arranged successively and adjacent to each other.

As shown in FIG. 11, the intermediate area 105 spaces the main light emitting area 101 from the secondary light emitting area 103. A width W1 of the intermediate area 105 is preferably greater than a width W2 of the secondary light emitting area 103, but the same is not required and the widths W1, W2 can be the same or the width W1 can be less than the width W2. The intermediate area 105 extends from an outer boundary of the main light emitting area 101 to an inner boundary of the secondary light emitting area 103, which corresponds to the width W1 shown in FIG. 11. The width W2 corresponds to the distance between an outer boundary of the secondary light emitting area 103 and the inner boundary of the secondary light emitting area 103. In embodiments where the width W1 is greater than the width W2, the width W1 can be 1%,-500% or more greater than the width W2 including intervening values. Thus, the width W1 can be 7% or 127% of the width W2 in some non-limiting examples. In embodiments where the intermediate area 105 emits light, the intermediate area 105 may emit light with the same or different characteristics than the main and secondary light emitting areas 101, 103. For example, the color of light emitted in the intermediate area 105 may be the same as the main and secondary light emitting areas 101, 103, but the light emitted in the intermediate area 105 may have different intensity or transmittance, meaning that less light is emitted in the intermediate area than in the main and/or secondary light emitting areas 101, 103. The light emitted in the intermediate area 105 originates from the first light emitting element ED1, similar to the main and secondary light emitting areas 101, 103, but has a different emission angle than the light emitted in the main and secondary light emitting areas 101, 103 to provide the light emitted in the intermediate area 105 with different characteristics.

The examples, aspects, and embodiments for the display device 100 and the display panel 110 described herein may be described as follows.

According to the one or more example embodiments described herein, a display device can be provided that includes a substrate, a first planarization layer disposed on the substrate, a second planarization layer disposed on the first planarization layer, and having a first hole allowing a first light emitting element to be disposed and having an inner surface including a first inclined surface and a second inclined surface and a second hole different from the first hole, a first pixel electrode disposed on the first planarization layer in the first hole and extending along the first inclined surface and the second inclined surface to an upper surface of the second planarization layer, a first black bank located in the second hole, a second black bank located on the second planarization layer, a third black bank located between the first inclined surface and the second inclined surface, a non-black bank disposed on the first black bank, the second black bank, the third black bank, and the first pixel electrode, a first intermediate layer disposed on a portion of the first pixel electrode and the non-black bank, and a common electrode disposed on the first intermediate layer.

In one or more aspects, the display device may further include an encapsulation layer disposed on the common electrode, a black matrix disposed on the encapsulation layer and having a first opening, and a first color filter disposed on the black matrix and overlapping with the first opening.

In one or more aspects, the display device may further include a first touch metal disposed on the encapsulation layer, a touch buffer layer disposed on the first touch metal, and a second touch metal disposed on the touch buffer layer and electrically connected to the first touch metal. In one or more aspects, at least one of the first touch metal and the second touch metal may overlap with the black matrix.

In one or more aspects, a first angle may be defined by the first inclined surface and a back surface of the second planarization layer, and a second angle may be defined by the second inclined surface and the back surface of the second planarization layer. In one or more aspects, the first angle may be less than the second angle.

In one or more aspects, the non-black bank may be a transparent bank.

In one or more aspects, the third black bank may be configured to absorb or reflect external light entering the display device.

In one or more aspects, the second black bank may further include at least one hole.

In one or more aspects, the display device may further include a common voltage line to which a common voltage is applied, and a first connection pattern electrically interconnecting the common electrode and the common voltage line. In one or more aspects, the first connection pattern may be located to overlap with the hole of the second black bank, be disposed on the second planarization layer, and include the same material as the first pixel electrode.

In one or more aspects, the first black bank may have a groove depressed downwardly from an upper surface of the first black bank.

In one or more aspects, the non-black bank includes a first trench overlapping with the second hole, and the first trench may correspond to the groove.

In one or more aspects, the display device may further include a spacer disposed on the non-black bank, and the spacer may overlap with the second black bank.

In one or more aspects, the first inclined surface may be configured to reflect first light emitted from the first light emitting element and cause the reflected first light to exit the display device.

In one or more aspects, as first light emitted from the first light emitting element is totally reflected by the common electrode, when the first light is reflected from a back surface of the common electrode, the second inclined surface may be configured to reflect the first light and cause the reflected first light exit the display device.

According to the one or more example embodiments described herein, a display device can be provided that includes a substrate, a first planarization layer disposed on the substrate, a second planarization layer disposed on the first planarization layer, and having a first hole allowing a first light emitting element to be disposed and having an inner surface including a first inclined surface and a second inclined surface and a second hole different from the first hole, a first pixel electrode disposed on the first planarization layer in the first hole and extending along the first inclined surface and the second inclined surface to an upper surface of the second planarization layer, a bank disposed on the first pixel electrode and the second planarization layer, a first intermediate layer disposed on a portion of the first pixel electrode and the bank, and a common electrode disposed on the first intermediate layer. In one or more aspects, a first angle formed by the first inclined surface and the back surface of the second planarization layer may be less than a second angle formed by the second inclined surface and the back surface of the second planarization layer.

In one or more aspects, the bank includes a first black bank located in the second hole, a second black bank disposed on the second planarization layer, and a third black bank located between the first inclined surface and the second inclined surface.

In one or more aspects, the bank may further include a non-black bank disposed on the first black bank, the second black bank, the third black bank, and the first pixel electrode, and the non-black bank may be a transparent bank.

In one or more aspects, the display device may further include a common voltage line to which a common voltage is applied, and a first connection pattern electrically interconnecting the common electrode and the common voltage line. In one or more aspects, the second black bank may further include at least one hole, and the first connection pattern may be located to overlap with the hole of the second black bank, be disposed on the second planarization layer, and include the same material as the first pixel electrode.

In one or more aspects, the first black bank may have a groove depressed downwardly from an upper surface of the first black bank, and the non-black bank includes a first trench overlapping with the second hole and corresponding to the groove.

In one or more aspects, the display device may further include an encapsulation layer disposed on the common electrode, a black matrix disposed on the encapsulation layer and having a first opening, and a first color filter disposed on the black matrix and overlapping with the first opening.

In one or more aspects, the display device may further include a first touch metal disposed on the encapsulation layer, a touch buffer layer disposed on the first touch metal, and a second touch metal disposed on the touch buffer layer and electrically connected to the first touch metal. In one or more aspects, at least one of the first touch metal and the second touch metal may overlap with the black matrix.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a plurality of layers;
a plurality of TFT layers on the substrate;
a plurality of planarization layers disposed on the TFT layers;
a sub-pixel disposed on the plurality of planarization layers and including an anode, wherein the sub-pixel is connected to the plurality of TFT layers and has a plurality of light emitting areas;
a black bank disposed on the plurality of planarization layers and covering at least a portion of the anode.

2. The display device of claim 1, wherein the black bank has a hole corresponding to the anode.

3. The display device of claim 2, wherein the substrate has a display area and a non-display area, the non-display area including a pad area, and
wherein the black bank is disposed in the pad area.

4. The display device of claim 3, wherein the black bank extends to an outermost edge of the substrate in the non-display area.

5. The display device of claim 3, wherein the pad area includes a source drain and the black bank covers at least a portion of the source drain.

6. The display device of claim 1, wherein the substrate has a display area and a non-display area, the display device further comprising:
a dam disposed on the substrate in the non-display area, wherein the dam overlaps an anode, a first source drain, and a second source drain of the non-display area, and
wherein the dam includes a plurality of layers and one layer of the plurality of layers is the black bank.

7. The display device of claim 6, wherein the dam is one of a plurality of dams that overlap the anode, the first source drain, and the second source drain.

8. The display device of claim 1, wherein the plurality of light emitting areas of the sub-pixel include a main light emitting area, an intermediate area, and a secondary light emitting area, wherein the intermediate area is between the main light emitting area and the secondary light emitting area.

9. The display device of claim 8, wherein the intermediate area is one of the plurality of light emitting areas and is configured to emit light.

10. The display device of claim 8, wherein the intermediate area is a non-emitting area that is configured to not emit light.

11. The display device of claim 8, wherein a width of the intermediate area is greater than a width of the secondary light emitting area.

12. The display device of claim 8, wherein the plurality of light emitting areas are configured to emit the same color of light.

13. The display device of claim 8, further comprising:
a light emitting element disposed on the substrate, wherein the plurality of light emitting areas are configured to emit light from the light emitting element.

14. The display device of claim 13, further comprising:
an encapsulation layer on the plurality of planarization layers;
a color filter layer on the encapsulation layer;
a black matrix between the encapsulation layer and the color filter layer,
wherein the black matrix has a hole corresponding to the light emitting element and the colter filter layer is disposed in the hole.

15. The display device of claim 14, wherein the hole in the black matrix corresponds to the main light emitting area of the plurality of light emitting areas, and the intermediate area and the secondary light emitting area both correspond to a location where the black matrix and the color filter layer overlap.

16. A display device, comprising:
a substrate having a plurality of layers;
a plurality of TFT layers on the substrate;
a plurality of planarization layers disposed on the TFT layers;
a sub-pixel disposed on the plurality of planarization layers and connected to the plurality of TFT layers, the sub-pixel having a main light emitting area, a secondary light emitting area, and an intermediate area between the main light emitting area and the secondary light emitting area; and
a black bank disposed on the plurality of planarization layers.

17. The display device of claim 16, wherein the sub-pixel includes an anode and the black bank covers at least a portion of the anode.

18. The display device of claim 16, wherein the plurality of TFT layers include a first active layer and a second active layer, and wherein a thickness of the first active layer is greater than a thickness of the second active layer.

19. The display device of claim 18, wherein the first active layer corresponds to an LPTS transistor and the second active layer corresponds to an oxide transistor.

20. The display device of claim 16, further comprising:
a light emitting element on the substrate, wherein the light emitting element includes a plurality of light emitting layers arranged in a tandem structure.

21. The display device of claim 16, wherein at least one of the plurality of planarization layers has a first inclined surface, a second inclined surface, and a ledge between the first inclined surface and the second inclined surface, the display device further comprising:
a hole through the at least one of the plurality of planarization layers corresponding to the first inclined surface and the second inclined surface;
a light emitting element disposed on the substrate in the hole; and
a bank on the ledge of the at least one of the plurality of planarization layers between the first inclined surface and the second inclined surface.

22. The display device of claim 21, wherein an angle between the first inclined surface and a rear surface of the planarization layer is less than an angle between the second inclined surface and the rear surface of the planarization layer.

23. The display device of claim 21, wherein the second inclined surface corresponds to a protrusion of the at least one of the plurality of planarization layers, the protrusion being a portion of the at least one planarization layer with a thickness greater than any other portion of the planarization layer.

24. The display device of claim 21, wherein:
the first inclined surface is configured to reflect first light emitted by the light emitting element and cause the first reflected light to exit the display device;
the second inclined surface is configured to reflect second light that is reflected by a rear surface of an electrode of the light emitting element and cause the second reflected light to exit the display device; and
the bank is configured to absorb or reflect external light entering the display device.

25. The display device of claim 21, further comprising:
a further hole through the at least one of the plurality of planarization layers,
wherein the bank includes a first black bank located in the further hole, a second black bank disposed on the at least one of the plurality of planarization layers, and a third black bank on the ledge of the at least one of the plurality of planarization layers between the first inclined surface and the second inclined surface.

26. The display device of claim 21, wherein the ledge corresponds to a flat and planar area of the at least one of the plurality of planarization layers between the first inclined surface and the second inclined surface.
